(19) United States
(12) Patent Application Publication
(10) Pub. No.: US 2026/0118751 A1
(43) Pub. Date: Apr. 30, 2026

(54) ORGANOMETALLIC COMPOUND, RESIST COMPOSITION COMPRISING THE SAME, AND PATTERN FORMATION METHOD USING THE RESIST COMPOSITION

(71) Applicant: Samsung Electronics Co., Ltd., Suwon-si (KR)

(72) Inventors: Jinwon JEON, Suwon-si (KR); Haengdeog KOH, Suwon-si (KR); Sunyoung LEE, Suwon-si (KR); Jiyoun LEE, Suwon-si (KR); Jungha CHAE, Suwon-si (KR); Changheon LEE, Suwon-si (KR)

(73) Assignee: Samsung Electronics Co., Ltd., Suwon-si (KR)

(21) Appl. No.: 19/003,296

(22) Filed: Dec. 27, 2024

(30) Foreign Application Priority Data
Jul. 26, 2024 (KR) 10-2024-0099638

(51) Int. Cl. G03F 7/004; C07F 7/22; G03F 7/00; H01L 21/027

(52) U.S. Cl. CPC G03F 7/0042; C07F 7/2224; G03F 7/0046; G03F 7/70341; H10P 76/2041

(57) ABSTRACT

Provided are an organometallic compound represented by Formula 1, a resist composition including the same, and a pattern formation method using the resist composition,

M₁₁(Rₓ)ₙ(R_{y})₍ₘ₋ₙ₎, Formula 1
wherein reference should be made to the specification for the descriptions of M₁₁, Rₓ, R_{y}, n and m in Formula 1.

### CROSS-REFERENCE TO RELATED APPLICATION

This application is based on and claims priority under 35 USC § 119 to Korean Patent Application No. 10-2024-0099638, filed on Jul. 26, 2024, in the Korean Intellectual Property Office, the disclosure of which is incorporated by reference herein in its entirety.

### BACKGROUND

### 1. Field

The disclosure relates to an organometallic compound, a resist composition including the same, and/or a pattern formation method using the resist composition.

### 2. Description of the Related Art

In semiconductor manufacturing, resists may have physical properties that change in response to light and resists may be used to form fine patterns. Among these resists, chemically amplified resists may be used. In chemically amplified resists, an acid may be formed through a reaction between light and a photoacid generator, and the acid may react with a base resin again to change the solubility of the base resin with respect to a developer, thereby enabling patterning.

However, in the case of chemically amplified resists, the diffusion of the formed acid into non-exposed areas may lead to poor pattern uniformity and increased surface roughness. In addition, with increasingly miniaturized semiconductor processes, it may be difficult to control the diffusion of acids, and thus there may be a need to develop a new type of resist.

Recently, in order to overcome the limits of chemically amplified resists, attempts have been made to develop materials of which physical properties change due to exposure to light. However, the dose required for exposure may be high.

### SUMMARY

Provided are a resist composition whose properties change even with low doses of exposure, and which provides patterns of improved resolution, and a method of forming a pattern using the resist composition.

Additional aspects will be set forth in part in the description which follows and, in part, will be apparent from the description, or may be learned by practice of the presented embodiments of the disclosure.

According to an embodiment of the disclosure, an organometallic compound may be represented by Formula 1:

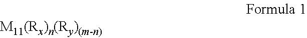

wherein, in Formula 1,
M₁₁ may be indium (In), tin (Sn), antimony (Sb), tellurium (Te), thallium (Tl), lead (Pb), bismuth (Bi), or polonium (Po),
Rₓ may be *—X₁-(L₁)ₐ₁-[Y₁—Z₁]_{c1},
R_{y} may be *-(L₂)ₐ₂-(R₁)_{b1},
n may be an integer from 1 to 6,
m may be an integer from 1 to 6,
m-n may be 0 or more,
a plurality of Rₓ may be identical to or different from each other,
a plurality of R_{y} may be identical to or different from each other,
X₁ may be O, OC(═O), C(═O)O, OS(═O), S(═O)O, OS(═O)₂, S(═O)₂O, S, SC(═O) or C(═O)S,
Y₁ may be OC(═O), C(═O)O, OS(═O)₂ or S(═O)₂O,
Z₁ may be *—C(R₂)(R₃)(R₄), *—C(R₂)═N(R₃), C(R₂)(R₃)═N—* or *—N(R₂)(R₃),
L₁ and L₂ may each independently be a linear, branched or cyclic C₁-C₃₀ divalent hydrocarbon group optionally including a heteroatom,
a1 and a2 may each independently be an integer from 0 to 4,
R₁ may be a linear, branched or cyclic C₁-C₃₀ monovalent hydrocarbon group optionally including a heteroatom, and an adjacent two of the plurality of R₁ may be optionally bound to each other to form a ring,
R₂ to R₄ may each independently be hydrogen, deuterium, a halogen atom, a cyano group, a hydroxyl group, or a linear, branched or cyclic C₁-C₃₀ monovalent hydrocarbon group optionally including a heteroatom, and an adjacent two of the plurality of R₂ to R₄ may be optionally bound to each other to form a ring,
b1 and c1 may each independently be an integer from 1 to 4, and
* may be a bonding site with a neighboring atom.

According to an embodiment of the disclosure of the disclosure, a resist composition may include the above-described organometallic compound.

According to an embodiment of the disclosure, a method of forming a pattern may include forming a resist film by applying the above-described resist composition on a substrate, exposing at least a portion of the resist film to high-energy rays to provide an exposed resist film, and developing the exposed resist film using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a method of forming a pattern, according to an embodiment;

FIGS. 2A to 2C are side cross-sectional views showing a method of forming a pattern, according to an embodiment;

FIGS. 3A to 3E are cross-sectional side views showing a method of forming a patterned structure, according to an embodiment;

FIGS. 4A to 4E are side cross-sectional views showing a method of forming a semiconductor device, according to an embodiment;

FIGS. 5A to 5D are graphs showing changes in film thickness after development according to dose, in Example 1-1 and Comparative Examples 1-1 to 1-6; and

FIGS. 6A to 6C are graphs showing the relative sizes of the residual film ratios of Example 1-1 and Comparative Examples 1-1, 1-3, and 1-5, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As the disclosure allows for various changes and numerous embodiments, particular embodiments will be illustrated in the drawings and described in detail in the written description. However, this is not intended to limit the disclosure to particular modes of practice, and it is to be appreciated that all modifications, equivalents, and substitutes that do not depart from the spirit and technical scope of the disclosure are encompassed in the disclosure. In describing the disclosure, when it is determined that the specific description of the known related art unnecessarily obscures the gist of the disclosure, the detailed description thereof will be omitted.

Although the terms “first”, “second”, “third”, and the like may be used herein to describe various elements, these terms are only used to distinguish one element from another and the order, type, or the like of the elements are not limited thereby.

A portion of a layer, film, region, plate, or the like described as being “on” or “above” another portion as used herein, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

The expression “Cₓ-C_{y}” used herein refers to the case where the number of carbon atoms constituting a substituent is in a range of x to y. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

The term “monovalent hydrocarbon group” used herein refers to a monovalent residue derived from an organic compound including carbon and hydrogen or a derivative thereof, and specific examples thereof include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e. g., a phenyl group, a 1-naphthyl group, and a 2-naphthyl group); an arylalkyl group (e. g., a benzyl group and a diphenylmethyl group); a heteroatom-including monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or a combination thereof. Additionally, some of hydrogens in these groups may be substituted with a moiety including a heteroatom such as oxygen, sulfur, nitrogen, or halogen atoms, or some of carbons in these groups may be replaced by a moiety including a heteroatom such as oxygen, sulfur, or nitrogen, and thus these groups may include a hydroxyl group, a cyano group, a carbonyl group, a carboxyl group, an ether bond, an ester bond, a sulfonate ester bond, a carbonate, a lactone ring, a sultone ring, a carboxylic anhydride moiety, or a haloalkyl moiety.

The term “divalent hydrocarbon group” as used herein is a divalent residue and refers to a system in which any one hydrogen atom of the monovalent hydrocarbon group is replaced by a bonding site with a neighboring atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic monovalent hydrocarbon group, and examples thereof may include a methyl group, an ethyl group, a propyl group, an isobutyl group, a sec-butyl group, a tert-butyl group, a pentyl group, an iso-amyl group, and a hexyl group. The term “alkylene group” as used herein refers to a linear or branched saturated aliphatic divalent hydrocarbon group, and examples thereof may include a methylene group, an ethylene group, a propylene group, a butylene group, and an isobutylene group.

The term “halogenated alkyl group” as used herein refers to a group in which at least one substituent of an alkyl group is substituted with a halogen atom, and examples thereof include CF₃. The halogen atom is F, Cl, Br or I.

The term “alkoxy group” as used herein refers to a monovalent group represented by formula —OA₁₀₁, wherein A₁₀₁ is an alkyl group. Specific examples thereof include a methoxy group, an ethoxy group, an isopropyloxy group, and the like.

The term “alkylthio group” as used herein refers to a monovalent group represented by formula —SA₁₀₁, wherein A₁₀₁ is an alkyl group.

The term “halogenated alkoxy group” as used herein refers to a group in which one or more hydrogen atoms of an alkoxy group are substituted with a halogen atom, and specific examples thereof include —OCF₃ and the like.

The term “halogenated alkylthio group” as used herein refers to a group in which one or more hydrogen atoms of an alkylthio group are substituted with a halogen atom, and specific examples thereof include —SCF₃ and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group represented by formula —OA₁₀₂, wherein A₁₀₂ is a cycloalkyl group. Specific examples thereof include a cyclopropoxy group, a cyclobutoxy group, and the like.

The term “cycloalkylthio group” as used herein refers to a monovalent group represented by formula —SA₁₀₂, where A₁₀₂ is a cycloalkyl group.

The term “heterocycloalkyl group” as used herein refers to a cycloalkyl group in which some carbon atoms are substituted with a moiety including a heteroatom, such as oxygen, sulfur, or nitrogen, and the heterocycloalkyl group may include an ether bond, an ester bond, a sulfonate ester bond, a carbonate, a lactone ring, a sultone ring, or a carboxylic anhydride moiety. The term “heterocycloalkylene group” as used herein refers to a group in which some carbon atoms of the cycloalkylene group are substituted with a moiety including a heteroatom such as oxygen, sulfur, or nitrogen.

The term “heterocycloalkoxy group” as used herein refers to a monovalent group represented by formula —OA₁₀₃, wherein A₁₀₃ is a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “cycloalkenyl group” as used herein refers to a monovalent unsaturated hydrocarbon cyclic group including at least one carbon-carbon double bond. The term “cycloalkenylene group” as used herein refers to a divalent unsaturated hydrocarbon cyclic group including at least one carbon-carbon double bond.

The term “heterocycloalkenyl group” as used herein refers to a cycloalkenyl group in which some carbon atoms are substituted with a moiety including a heteroatom, such as oxygen, sulfur, or nitrogen. The term “heterocycloalkenylene group” as used herein refers to a cycloalkenylene group in which some carbon atoms are substituted with a moiety including a heteroatom, such as oxygen, sulfur, or nitrogen.

The term “alkynyl group” as used herein refers to a linear or branched monovalent unsaturated aliphatic hydrocarbon group including one or more carbon-carbon triple bonds.

The term “aryl group” as used herein refers to a monovalent group including a carbocyclic aromatic system, and examples thereof include a phenyl group, a naphthyl group, an anthracenyl group, a phenanthrenyl group, a pyrenyl group, and a chrysenyl group. The term “arylene group” as used herein refers to a divalent group including a carbocyclic aromatic system.

The term “heteroaryl group” as used herein refers to a monovalent group including a heterocyclic aromatic system, and examples thereof include a pyridinyl group, a pyrimidinyl group, and a pyrazinyl group. The term “heteroarylene group” as used herein refers to a divalent group including a heterocyclic aromatic system.

The term “substituent” as used herein includes deuterium, a halogen atom, a hydroxyl group, a cyano group, a nitro group, a carbonyl group, a carboxylate group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; and
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₅-C₂₀ cycloalkyl group, a C₅-C₂₀ cycloalkoxy group, a C₅-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and C₁-C₂₀ heteroarylthio group, each substituted with deuterium, a halogen atom, a hydroxyl group, a cyano group, a nitro group, a carbonyl group, a carboxylate group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, or a combination thereof; or a combination thereof.

Hereinafter, embodiments will be described in detail with reference to the accompanying drawings, wherein like reference numerals denote substantially the same or corresponding components throughout the drawings, and a redundant description thereof will be omitted. In the drawings, thicknesses of various layers and regions are enlarged for clarity. Also, in the drawings, the thicknesses of some layers and regions are exaggerated for convenience of description. Meanwhile, embodiments set forth hereinafter are merely for illustrative purposes, and various changes may be made therein.

### [Organometallic Compounds]

Organometallic compounds according to embodiments are represented by Formula 1:

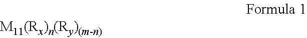

wherein, in Formula 1,
M₁₁ may be indium (In), tin (Sn), antimony (Sb), tellurium (Te), thallium (Tl), lead (Pb), bismuth (Bi), or polonium (Po),
Rₓ may be *—X₁-(L₁)ₐ₁-[Y₁—Z₁]_{c1},
R_{y} may be *-(L₂)ₐ₂-(R₁)_{b1},
n may be an integer from 1 to 6,
m may be an integer from 1 to 6,
m-n may be greater than or equal to 0 (e.g., 0 to 5),
a plurality of Rₓ may be identical to or different from each other,
a plurality of R_{y} may be identical to or different from each other,
X₁ may be O, OC(═O), C(═O)O, OS(═O), S(═O)O, OS(═O)₂, S(═O)₂O, S, SC(═O) or C(═O)S,
Y₁ may be OC(═O), C(═O)O, OS(═O)₂ or S(═O)₂O,
Z₁ may be *—C(R₂)(R₃)(R₄), *—C(R₂)═N(R₃), C(R₂)(R₃)═N—* or *—N(R₂)(R₃),
L₁ and L₂ may each independently be a linear, branched or cyclic C₁-C₃₀ divalent hydrocarbon group optionally including a heteroatom,
a1 and a2 may each independently be an integer from 0 to 4,
R₁ may be a linear, branched or cyclic C₁-C₃₀ monovalent hydrocarbon group optionally including a heteroatom, and an adjacent two of the plurality of R₁ may be optionally bound to each other to form a ring,
R₂ to R₄ may each independently be hydrogen, deuterium, a halogen atom, a cyano group, a hydroxyl group, or a linear, branched or cyclic C₁-C₃₀ monovalent hydrocarbon group optionally including a heteroatom, and an adjacent two of the plurality of R₂ to R₄ may be optionally bound to each other to form a ring,
b1 and c1 may each independently be an integer from 1 to 4, and
* may be a bonding site with a neighboring atom.

The molecular weight of the organometallic compound may be about 3000 g/mol or less. For example, the molecular weight of the organometallic compound may be about 2000 g/mol or less.

For example, in Formula 1, M₁₁ may be Sn, Sb, Te or Bi. For example, in Formula 1, M₁₁ may be Sn.

In Formula 1, m represents the valence of M₁₁.

For example, in Formula 1, n may be an integer from 1 to 4.

For example, in Formula 1, m may be an integer from 1 to 3.

In an embodiment, in Formula 1, n may be an integer from 1 to 4, m may be an integer from 1 to 3, and M₁₁ may be Sn.

In Formula 1, the bond between M₁₁ and Rₓ may be an M₁₁-oxygen single bond or an M₁₁-sulfur single bond. For example, in Formula 1, the bond between M₁₁ and Rₓ may be an M₁₁-oxygen single bond.

In Formula 1, the bond between M₁₁ and R_{y} may be an M₁₁-carbon single bond.

For example, in Formula 1, X₁ may be O, OC(═O), or C(═O)O.

For example, in Formula 1, Y₁ may be OC(═O), C(═O)O, OS(═O)₂, or S(═O)₂O.

For example, in Formula 1, L₁ and L₂ may each independently be a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

For example, in Formula 1, L₁ and L₂ may each independently be selected from a C₁-C₃₀ alkylene group, a C₃-C₃₀ cycloalkylene group, a C₃-C₃₀ heterocycloalkylene group, a C₂-C₃₀ alkenylene group, a C₅-C₃₀ cycloalkenylene group, a C₃-C₃₀ heterocycloalkenylene group, a C₆-C₃₀ arylene group, and a C₁-C₃₀ heteroarylene group, each unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₅-C₂₀ cycloalkyl group, a C₃-C₂₀ cycloalkoxy group, a C₃-C₂₀ cycloalkylthio group, a C₆-C₃₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

For example, in Formula 1, L₁ and L₂ may each independently be selected from a C₁-C₃₀ alkylene group and a C₆-C₃₀ arylene group, each unsubstituted or substituted with deuterium, a halogen atom, a hydroxyl group, a cyano group, a C₁-C₂₀ alkyl group, a C₁-C₂₀ halogenated alkyl group, or a combination thereof.

For example, in Formula 1, a1 and a2 may each independently be an integer from 0 to 2.

For example, in Formula 1, a1 may be 1 or 2.

For example, in Formula 1, a2 may be 0 or 1.

In an embodiment, in Formula 1, (L₁)ₐ₁ may be represented by any one of Formulae 5-1 to 5-7:

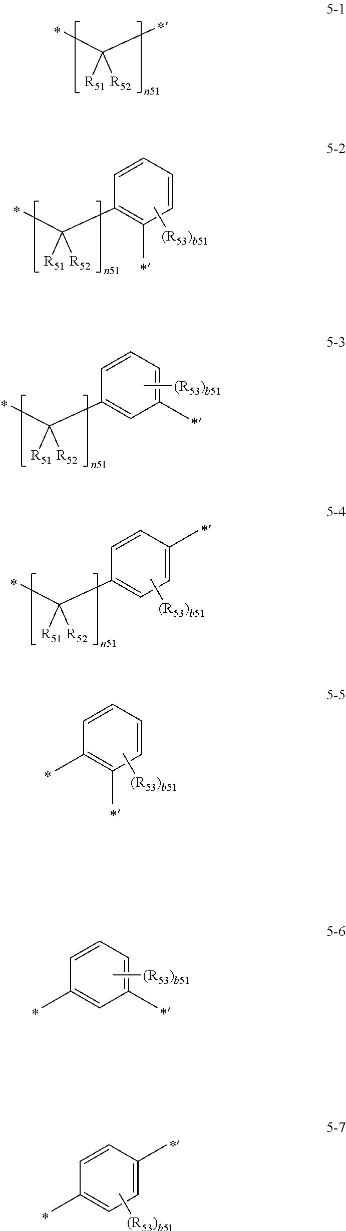

wherein, in Formulae 5-1 to 5-7,
R₅₁ to R₅₃ may each independently be hydrogen, deuterium, a halogen atom, a hydroxyl group, a cyano group, a C₁-C₄ alkyl group, or a C₁-C₄ halogenated alkyl group,
b51 may be an integer from 1 to 4,
n51 may be an integer from 1 to 4,
* and *′ may be a bonding site with a neighboring atom.

In Formula 1, R₁ may be a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ an aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group or a substituted or unsubstituted C₁-C₃₀ heteroarylthio group,
R₂ to R₄ may each independently be hydrogen, deuterium, a halogen atom, a cyano group, a nitro group, a hydroxyl group, —C(═O)R₅, —C(R₅)═NR₆, —OR₅, —S(═O)R₅, —S(═O)₂R₅, —S(═O)₂OR₅, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group or a substituted or unsubstituted C₁-C₃₀ heteroarylthio group, and
R₅ and R₆ may each independently be hydrogen, deuterium, a hydroxyl group, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group.

For example, R₁ may be selected from a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₅-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group or a combination thereof,
R₂ to R₄ may each independently be selected from hydrogen; deuterium; a halogen atom; a cyano group; a nitro group; a hydroxyl group; —C(═O)R₅; —C(R₅)═NR₆; —S(═O)₂R₅; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₅-C₂₀ cycloalkyl group, a C₃-C₂₀ cycloalkoxy group, a C₃-C₂₀ cycloalkylthio group, a C₆-C₂₀ aryl group, a C₁-C₂₀ a heteroaryl group, a C₆-C₂₀ aryloxy group, a C₆-C₂₀ arylthio group, a C₁-C₂₀ heteroaryloxy group, a C₁-C₂₀ heteroarylthio group or a combination thereof, and
R₅ and R₆ may each independently be hydrogen; deuterium; a hydroxyl group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₅-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group or a combination thereof.

For example, in Formula 1, R₁ may be selected from a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group or a combination thereof,
R₂ to R₄ may each independently be selected from hydrogen; deuterium; a halogen atom; a cyano group; a nitro group; a hydroxyl group; —C(O)R₅; —C(R₅)═NR₆; —S(═O)₂R₅; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group or a combination thereof, and
R₅ and R₆ may each independently be selected from hydrogen; deuterium; a hydroxyl group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group or a combination thereof.

In Formula 1, R₁ may be selected from any one of Formulae 3-1 to 3-21,
R₂ to R₄ may each independently be selected from hydrogen; deuterium; a halogen atom; a cyano group; a nitro group; a hydroxyl group; —C(═O)R₅; —C(R₅)═NR₆; —S(═O)₂R₅; and any one of Formulae 3-1 to 3-21, and
R₅ and R₆ may each independently be selected from hydrogen; deuterium; a hydroxyl group; and any one of Formulae 3-1 to 3-21:

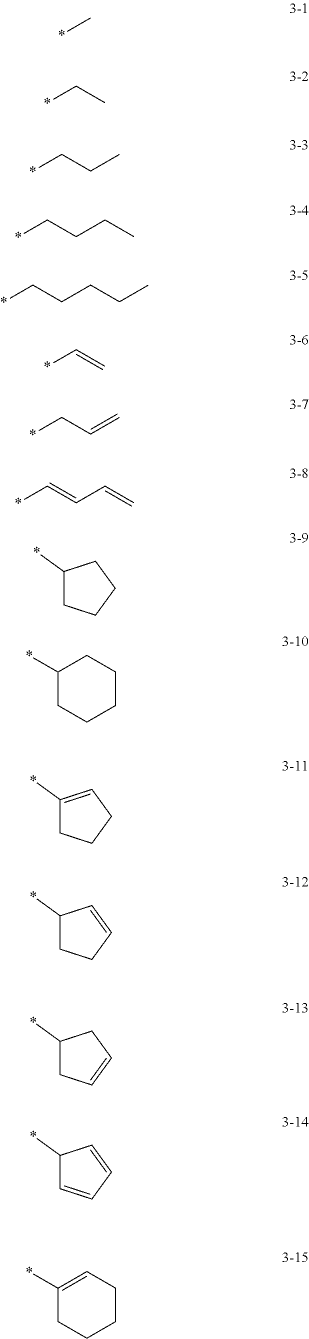

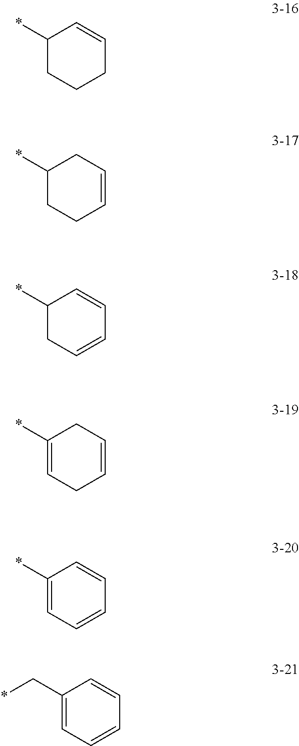

wherein, in Formulae 3-1 to 3-21,
at least one hydrogen may be optionally substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group or a combination thereof.

In an embodiment, in Formula 1, Z₁ may be represented by any one of Formulae 4-1 to 4-9:

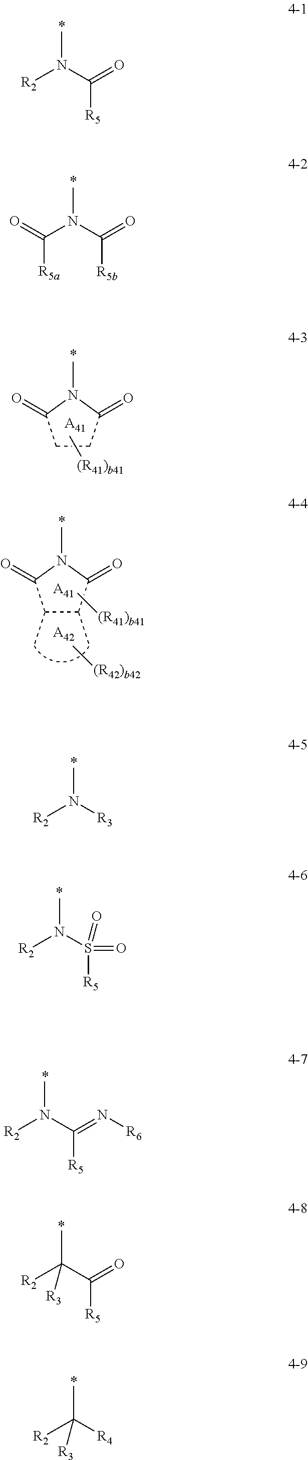

wherein, in Formulae 4-1 to 4-9,
R₂ to R₄ may each independently be selected from hydrogen; deuterium; a halogen atom; a cyano group; a nitro group; a hydroxyl group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group or a combination thereof,
R₅, R₅ₐ and R_{5b} may each independently be selected from hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group or a combination thereof,
an adjacent two selected from: R₂ to R₅; R₅ₐ; and R_{5b} may optionally be bound to each other to form a ring,
A₄₁ and A₄₂ may each independently be a cyclic C₁-C₃₀ alkyl group optionally including a heteroatom or a C₁-C₃₀ aryl group optionally including a heteroatom,
R₄₁ and R₄₂ may each independently be hydrogen, deuterium, a halogen atom, a hydroxyl group, a cyano group, a nitro group, a C₁-C₂₀ alkyl group, a C₁-C₂₀ halogenated alkyl group, a C₃-C₂₀ cycloalkyl group, a C₆-C₂₀ aryl group, or a C₁-C₂₀ heteroaryl group,
b41 and b42 may each independently be an integer from 1 to 10, and
* is a bonding site with a neighboring atom.

In an embodiment, in Formula 1, Z₁ may be represented by any one of Formulae 4-11 to 4-50:

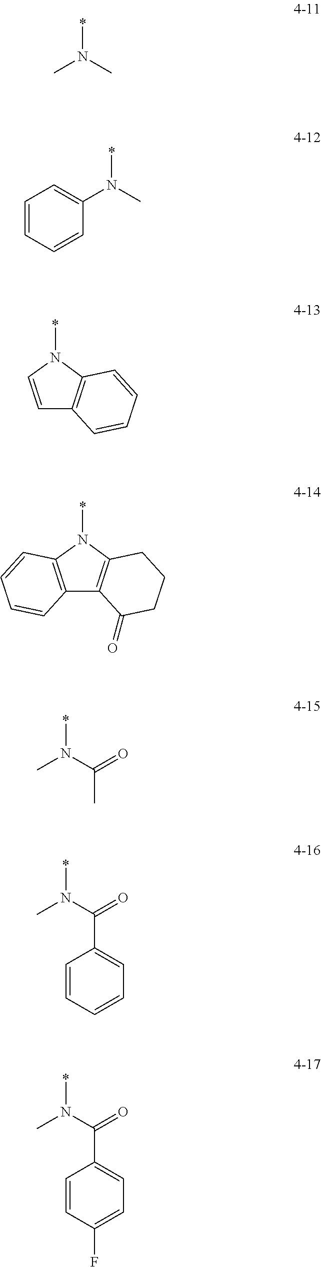

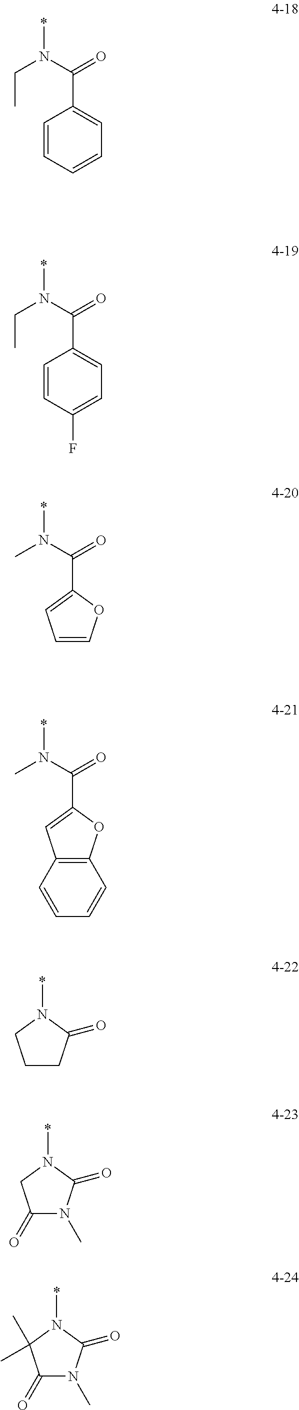

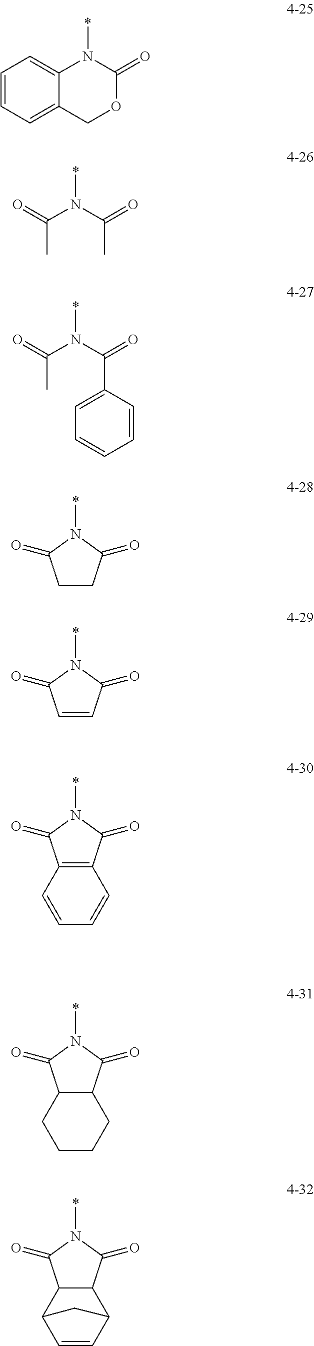

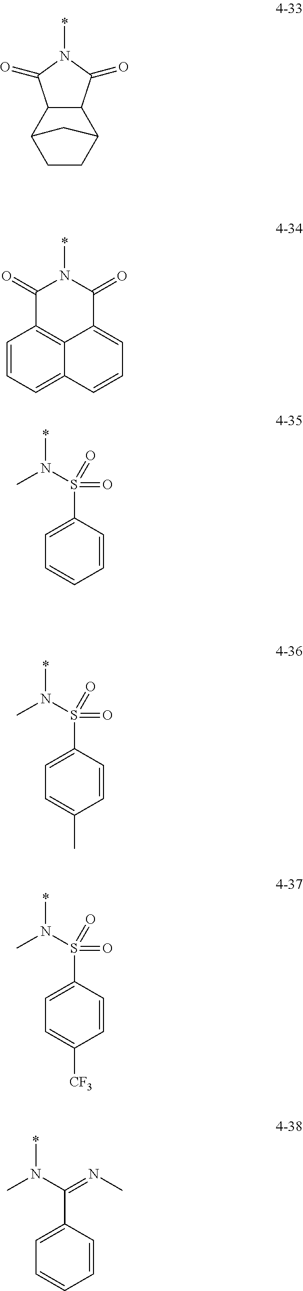

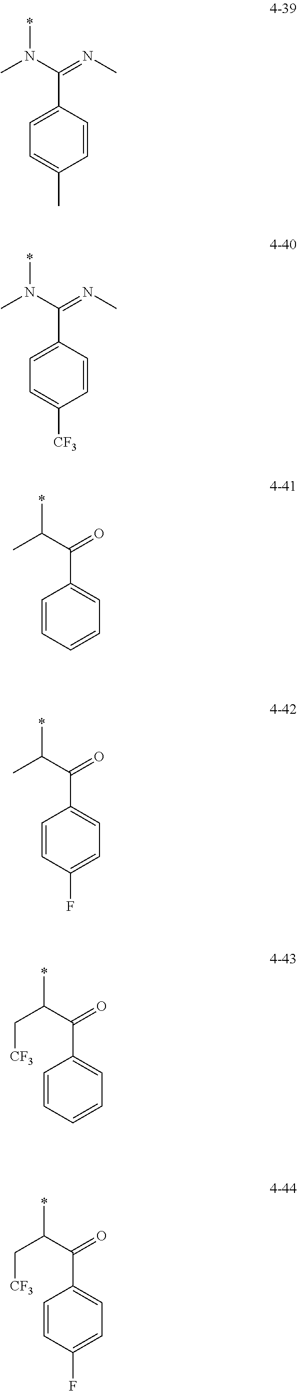

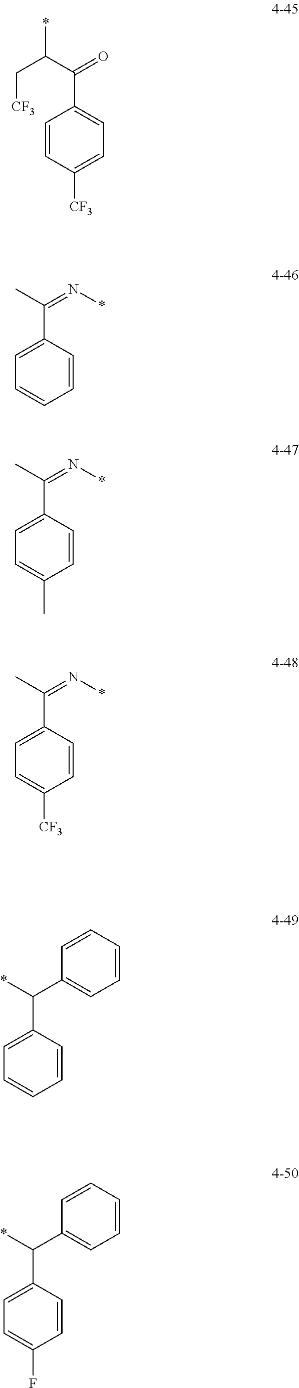

wherein, in Formulae 4-11 to 4-50,
* is a bonding site with a neighboring atom.

In an embodiment, in Formula 1, b1 may be greater than or equal to 2 (e.g., 2, 3, or 4), and R₁ may be selected from a C₂-C₃₀ alkenyl group, a C₃-C₃₀ cycloalkenyl group, a C₂-C₃₀ alkynyl group and a C₆-C₃₀ aryl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or a combination thereof.

In an embodiment, at least one of R₂ to R₄ in Formula 1 may be an electron withdrawing group.

In an embodiment, in Formula 1, at least one of R₂ to R₄ may be selected from halogen; a cyano group; a nitro group; —C(═O)R₅; —C(R₅)═NR₆; —S(═O)₂R₅; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each substituted with a halogen atom, a cyano group, a nitro group, a C₁-C₂₀ halogenated alkyl group, or a combination thereof, and
R₅ and R₆ may each independently be selected from hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group or a combination thereof.

In an embodiment, the organometallic compound represented by Formula 1 may be represented by any one of Formulae 1-1 to 1-4:

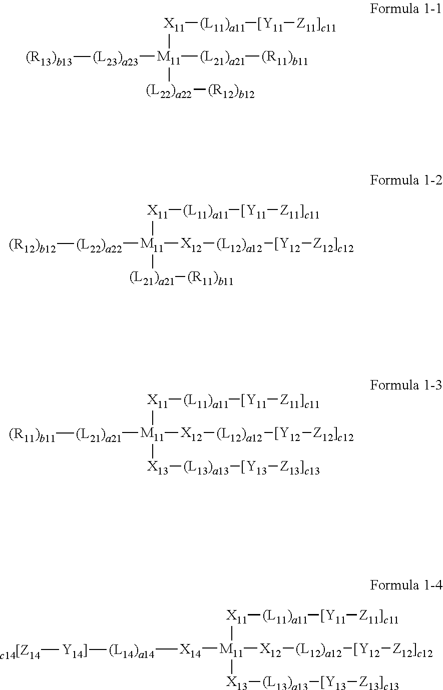

wherein, in Formulae 1-1 to 1-4,
M₁₁ may be the same as the definition in Formula 1,
L₁₁ to L₁₄ may each independently be the same as the definition of L₁ in Formula 1,
L₂₁ to L₂₃ may each independently be the same as the definition of L₂ in Formula 1,
a11 to a14 may each independently be the same as the definition of a1 in Formula 1,
a21 to a23 may each independently be the same as the definition of a2 in Formula 1,
R₁₁ to R₁₃ may each independently be the same as the definition of R₁ in Formula 1,
b11 to b13 may each independently be the same as the definition of b1 in Formula 1,
Y₁₁ to Y₁₄ may each independently be the same as the definition of Y₁ in Formula 1,
X₁₁ to X₁₄ may each independently be the same as the definition of X₁ in Formula 1,
Z₁₁ to Z₁₄ may each independently be the same as the definition of Z₁ in Formula 1, and
c11 to c14 may each independently be the same as the definition of c1 in Formula 1.

In an embodiment, the organometallic compound represented by Formula 1 may be selected from the following Group I:

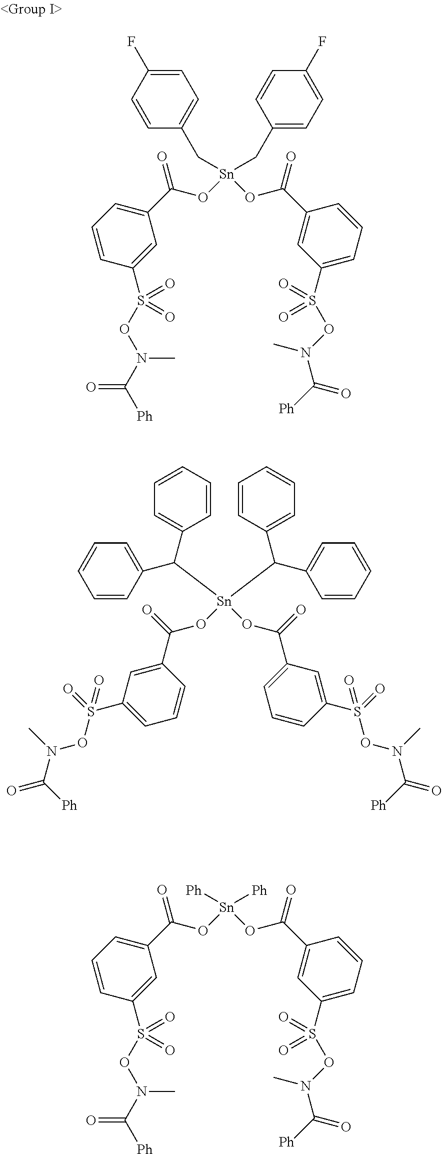 [SMILES: CN(OS(=O)(=O)c1cccc(C(=O)[O][Sn]([CH2]c2ccc(F)cc2)([CH2]c2ccc(F)cc2)[O]C(=O)c2cccc(S(=O)(=O)ON(C)C(=O)c3ccccc3)c2)c1)C(=O)c1ccccc1 ; CN(OS(=O)(=O)c1cccc(C(=O)[O][Sn]([O]C(=O)c2cccc(S(=O)(=O)ON(C)C(=O)c3ccccc3)c2)([CH](c2ccccc2)c2ccccc2)[CH](c2ccccc2)c2ccccc2)c1)C(=O)c1ccccc1 ; CN(OS(=O)(=O)c1cccc(C(=O)[O][Sn]([O]C(=O)c2cccc(S(=O)(=O)ON(C)C(=O)c3ccccc3)c2)([c]2ccccc2)[c]2ccccc2)c1)C(=O)c1ccccc1]

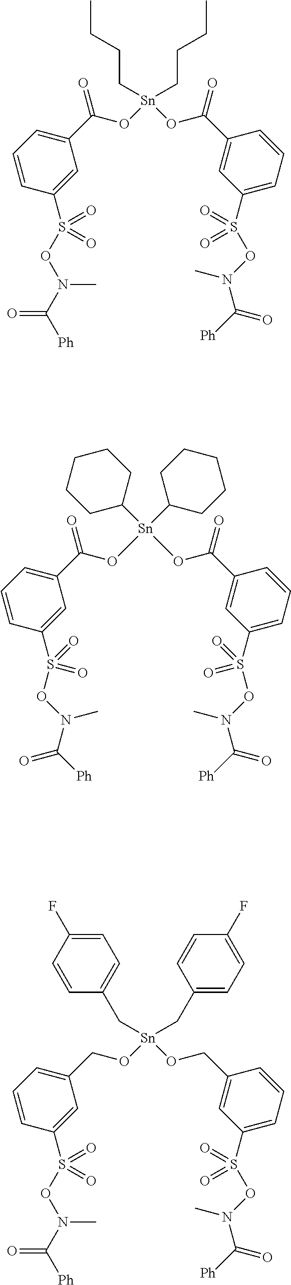 [SMILES: CCC[CH2][Sn]([CH2]CCC)([O]C(=O)c1cccc(S(=O)(=O)ON(C)C(=O)c2ccccc2)c1)[O]C(=O)c1cccc(S(=O)(=O)ON(C)C(=O)c2ccccc2)c1 ; CN(OS(=O)(=O)c1cccc(C(=O)[O][Sn]([O]C(=O)c2cccc(S(=O)(=O)ON(C)C(=O)c3ccccc3)c2)([CH]2CCCCC2)[CH]2CCCCC2)c1)C(=O)c1ccccc1 ; CN(OS(=O)(=O)c1cccc(C[O][Sn]([CH2]c2ccc(F)cc2)([CH2]c2ccc(F)cc2)[O]Cc2cccc(S(=O)(=O)ON(C)C(=O)c3ccccc3)c2)c1)C(=O)c1ccccc1]

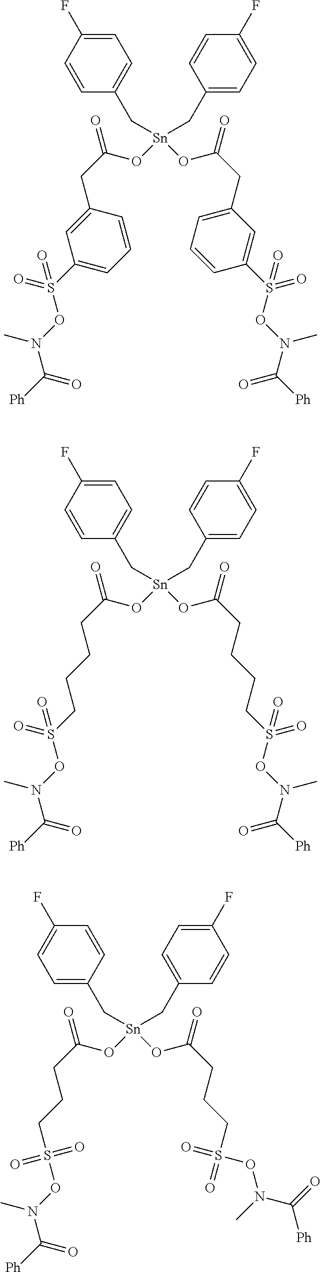

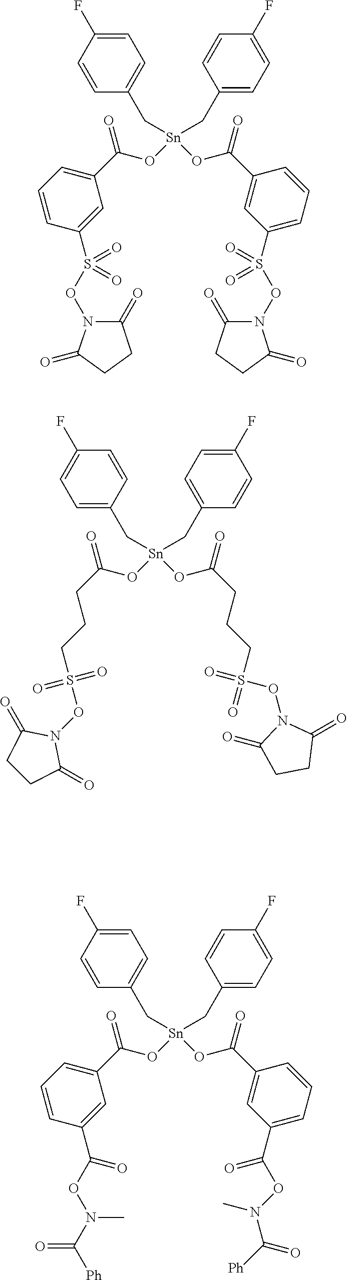 [SMILES: O=C([O][Sn]([CH2]c1ccc(F)cc1)([CH2]c1ccc(F)cc1)[O]C(=O)c1cccc(S(=O)(=O)ON2C(=O)CCC2=O)c1)c1cccc(S(=O)(=O)ON2C(=O)CCC2=O)c1 ; O=C(CCCS(=O)(=O)ON1C(=O)CCC1=O)[O][Sn]([CH2]c1ccc(F)cc1)([CH2]c1ccc(F)cc1)[O]C(=O)CCCS(=O)(=O)ON1C(=O)CCC1=O ; CN(OC(=O)c1cccc(C(=O)[O][Sn]([CH2]c2ccc(F)cc2)([CH2]c2ccc(F)cc2)[O]C(=O)c2cccc(C(=O)ON(C)C(=O)c3ccccc3)c2)c1)C(=O)c1ccccc1]

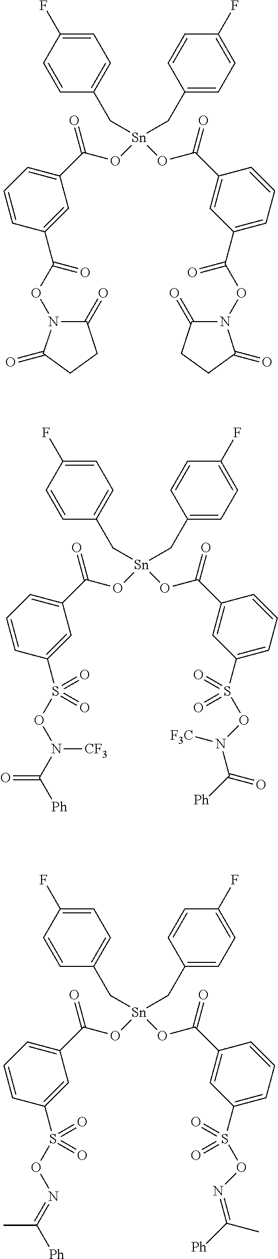 [SMILES: O=C(ON1C(=O)CCC1=O)c1cccc(C(=O)[O][Sn]([CH2]c2ccc(F)cc2)([CH2]c2ccc(F)cc2)[O]C(=O)c2cccc(C(=O)ON3C(=O)CCC3=O)c2)c1 ; O=C([O][Sn]([CH2]c1ccc(F)cc1)([CH2]c1ccc(F)cc1)[O]C(=O)c1cccc(S(=O)(=O)ON(C(=O)c2ccccc2)C(F)(F)F)c1)c1cccc(S(=O)(=O)ON(C(=O)c2ccccc2)C(F)(F)F)c1 ; C/C(=N\OS(=O)(=O)c1cccc(C(=O)[O][Sn]([CH2]c2ccc(F)cc2)([CH2]c2ccc(F)cc2)[O]C(=O)c2cccc(S(=O)(=O)O/N=C(\C)c3ccccc3)c2)c1)c1ccccc1]

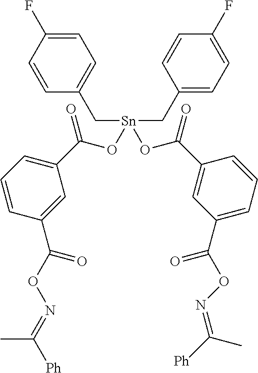 [SMILES: C/C(=N\OC(=O)c1cccc(C(=O)[O][Sn]([CH2]c2ccc(F)cc2)([CH2]c2ccc(F)cc2)[O]C(=O)c2cccc(C(=O)O/N=C(\C)c3ccccc3)c2)c1)c1ccccc1]

Although not limited to a specific theory, the organometallic compound may undergo a change in polarity due to dissociation of specific bonds by high-energy rays (e.g., ultraviolet rays, deep ultraviolet rays, extreme ultraviolet rays, X-rays, and γ-rays).

For example, the organometallic compound may form a radical from Rₓ by high-energy rays, and optionally, in the presence of water, the radical may be reacted to generate a polar functional group. As a result, the properties of the organometallic compound, particularly its solubility in a developer, may change due to high-energy rays.

The organometallic compound may exhibit a water contact angle difference of 25° or more, 40° or more, 50° or more, or 60° or more, before and after exposure. In this case, the exposure dose may be 100 mJ/cm² or less, 80 mJ/cm² or less, 60 mJ/cm² or less, or 50 mJ/cm² or less.

The organometallic compound may exhibit a water contact angle difference of 25° or more, or 30° or more, before and after exposure with an exposure dose of 100 mJ/cm² or less, and in particular, the water contact angle difference may be 25° or more, or 30° or more, before and after exposure with an exposure dose of 80 mJ/cm² or less.

The organometallic compound may be prepared by any suitable method.

The structure (composition) of the organometallic compound may be confirmed by performing FT-IR analysis, NMR analysis, X-ray fluorescence (XRF) analysis, mass spectrometry, UV analysis, single crystal X-ray structural analysis, powder X-ray diffraction (PXRD) analysis, liquid chromatography (LC) analysis, size exclusion chromatography (SEC) analysis, thermal analysis, etc. The detailed confirmation method is as described in the examples.

### [Resist Composition]

According to another aspect of the disclosure, a resist composition includes the above-described organometallic compound. The resist composition may have improved photosensitivity and/or storage stability properties.

The solubility of the resist composition in a developer changes upon exposure to high-energy rays. The resist composition may be a positive resist composition in which an exposed portion of the resist film is dissolved and removed to form a resist pattern.

In addition, the resist composition may be used for a distilled water developing process using distilled water (DI) for developing treatment when forming a resist pattern, or used for an alkaline developing process using an alkaline developer, or used for a solvent developing process using a developer including an organic solvent for the developing treatment (hereinafter, also referred to as an organic developer).

In particular, the resist composition may provide a pattern with improved critical dimension (CD) uniformity by using distilled water (DI) or an organic solvent as a developer, or by using an alkaline developer including a relatively small amount of alkaline components.

Since the resist composition is a non-chemically amplified type, the resist composition may be substantially free of a photoacid generator.

The resist composition may not substantially include a compound having a molecular weight of 1,000 or more other than the organometallic compound, since the properties of the organometallic compound change upon exposure.

In the resist composition, the organometallic compound may be present in an amount of about 0.1 parts by weight to about 100 parts by weight, 0.2 or more, 0.5 or more, 1 or more, 2 or more, 90 or less, or 80 or less parts by weight, based on 100 parts by weight of the composition. When the above-described range is satisfied, a film having a thickness required for pattern formation may be sufficiently formed and side reactions may be limited and/or suppressed, thereby providing a resist composition with improved sensitivity and/or resolution.

### <Organic Solvent>

The resist composition may further include an organic solvent.

The organic solvent included in the resist composition is not particularly limited, as long as the organometallic compound and any component included therein, if required, may be dissolved or dispersed therein. The organic solvent may be used alone, or any combination of two or more different organic solvents may also be used.

In an embodiment, the organic solvent may include a nonpolar solvent, a polar protic organic solvent, a polar aprotic organic solvent, or a combination thereof.

In another embodiment, the organic solvent may be a polar aprotic organic solvent.

Examples of polar protic solvents may include alcohol-based solvents.

Examples of polar aprotic solvents may include ether-based solvents, ketone-based solvents, amide-based solvents, ester-based solvents, and sulfoxide-based solvents.

Examples of nonpolar solvents may include hydrocarbon-based solvents.

Examples of the alcohol-based solvents include: a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxy butanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonylalcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyalcohol-based solvent such as ethyleneglycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethyleneglycol, dipropyleneglycol, triethylene glycol, and tripropylene glycol; and a polyalcohol-containing ether-based solvent such as ethyleneglycol monomethylether, ethyleneglycol monoethylether, ethyleneglycol monopropylether, ethyleneglycol monobutylether, ethyleneglycol monohexylether, ethyleneglycol monophenylether, ethyleneglycol mono-2-ethylbutylether, diethyleneglycol monomethylether, diethyleneglycol monoethylether, diethyleneglycol monopropylether, diethyleneglycol monobutylether, diethyleneglycol monohexyl ether, diethylene glycol dimethylether, propylene glycol monomethylether, propylene glycol dimethylether, propylene glycol monoethylether, propylene glycol monopropylether, propylene glycol monobutylether, dipropyleneglycol monomethylether, dipropyleneglycol monoethylether, and dipropyleneglycol monopropylether.

Examples of the ether-based solvents include: a dialkylether-based solvent such as diethylether, dipropylether, dibutylether, diethylene glycol dimethyl ether, and dipropylene glycol dimethyl ether; a cyclic ether-based solvent such as tetrahydrofuran and tetrahydropyran; and an aromatic ring-containing ether-based solvent such as diphenylether and anisole.

Examples of the ketone-based solvents may include: a chain-shaped ketone-based solvent such as acetone, methylethylketone, methyl-n-propylketone, methyl-n-butylketone, methyl-n-pentylketone, diethylketone, methylisobutylketone, 2-heptanone, ethyl-n-butylketone, methyl-n-hexylketone, diisobutylketone, and trimethylnonanone; a cyclic ketone-based solvent such as cyclopentanone, cyclohexanone, cycloheptanone, cyclooctanone, and methylcyclohexanone; and 2,4-pentanedione, acetonylacetone, and acetphenone.

Examples of the amide-based solvents include: a cyclic amide-based solvent such as N,N′-dimethylimidazolidinone and N-methyl-2-pyrrolidone; and a chain-shaped amide-based solvent such as N-methylformamide, N,N-dimethylformamide, N,N-diethylformamide, acetamide, N-methylacetamide, N,N-dimethylacetamide, and N-methylpropyoneamide.

Examples of the ester-based solvents include: an acetate ester-based solvent such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyalcohol-containing ethercarboxylate-based solvent such as ethyleneglycol monomethylether acetate, ethyleneglycol monoethylether acetate, diethyleneglycol monomethylether acetate, diethyleneglycol monoethylether acetate, diethyleneglycol mono-n-butyl ether acetate, propylene glycol monomethylether acetate (PGMEA), propylene glycol monoethylether acetate, propylene glycol monopropylether acetate, propylene glycol monobutylether acetate, dipropylene glycol monomethylether acetate, and dipropylene glycol monoethylether acetate; a lactone-based solvent such as γ-butyrolactone and δ-valerolactone; a carbonate-based solvent such as dimethyl carbonate, diethyl carbonate, ethylene carbonate, and propylene carbonate; a lactate ester-based solvent such as methyl lactate, ethyl lactate, n-butyl lactate, and n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvents include dimethyl sulfoxide and diethyl sulfoxide.

Examples of the hydrocarbon-based solvents include: an aliphatic hydrocarbon-based solvent such as n-pentane, isopentane, n-hexane, isohexane, n-heptane, isoheptane, 2,2,4-trimethyl pentane, n-octane, isooctane, cyclohexane, and methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

For example, the organic solvent may include a chain-shaped ketone-based solvent, a cyclic ketone-based solvent, a polyalcohol-containing ethercarboxylate-based solvent, a lactone-based solvent, an acetate ester-based solvent, and a combination thereof.

For example, the organic solvent may include a cyclic ketone-based solvent, a polyalcohol-containing ethercarboxylate-based solvent, and a combination thereof.

In particular, the organic solvent may include cyclopentanone, cyclohexanone, cycloheptanone, propylene glycol monomethyl ether acetate, propylene glycol monoethyl ether acetate, propylene glycol monopropyl ether acetate, propylene glycol monobutyl ether acetate, and a combination thereof.

For example, the organic solvent may include cyclopentanone, cyclohexanone, cycloheptanone and a combination thereof.

Since the resist composition may be substantially free of water, the organic solvent may be free of water. For example, the resist composition may include 3 wt % or less of water, and the organic solvent may include 3 wt % or less of water.

### <Optional Component>

The resist composition may further include a surfactant, a cross-linking agent, a leveling agent, a colorant, or a combination thereof, if necessary.

The resist composition may further include a surfactant to improve coatability, developability, and the like. Examples of the surfactant may include a nonioinc surfactant such as polyoxyethylene lauryl ether, polyoxyethylene stearyl ether, polyoxyethyleneoleyl ether, polyoxyethylene n-octylphenyl ether, polyoxyethylene n-nonylphenyl ether, polyethyleneglycol dilaurate, and polyethyleneglycol distearate. Any commercially available product or a synthetic product may be used as the surfactant. Examples of the commercially available product may include KP341 (manufactured by Shin-Etsu Chemical Co., Ltd.), Polyflow No. 75 and Polyflow No. 95 (manufactured by Kyoeisha Chemical Co., Ltd.), Eftop EF301, Eftop EF303, and Eftop EF352 (manufactured by Mitsubishi Materials Electronic Chemicals Co., Ltd.), MEGAFACE® F171, MEGAFACE F173, R40, R41, and R43 (manufactured by DIC Corporation), Fluorad® FC430, Fluorad FC431 (manufactured by 3M Co., Ltd.), AsahiGuard AG710 (manufactured by AGC Co., Ltd.), and Surflon® S-382, Surflon SC-101, Surflon SC-102, Surflon SC-103, Surflon SC-104, Surflon SC-105, and Surflon SC-106 (manufactured by AGC Seimi Chemical Co., Ltd).

The surfactant may be included in an amount of about 0 parts by weight to about 20 parts by weight based on 100 parts by weight of the polymer. The surfactant may be used alone or any mixture of two or more different surfactants may also be used.

A method of preparing the resist composition is not particularly limited, and any method of mixing the polymer and optional components added as occasion demands in an organic solvent may also be used. Temperature or time in the mixing is not particularly limited. If necessary, filtration may be performed after the mixing.

### [Pattern Formation Method]

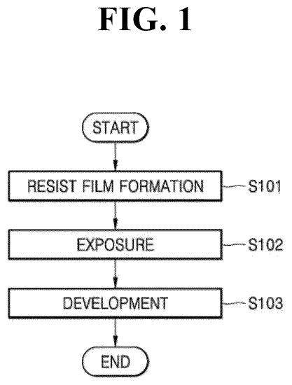

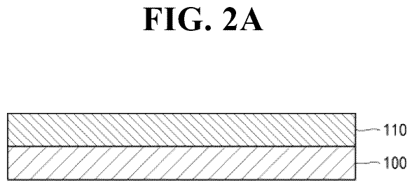

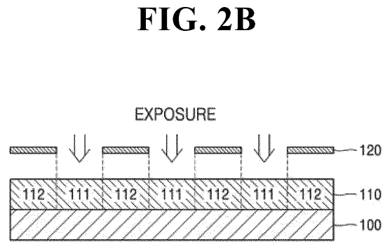

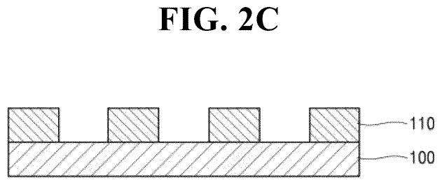

Hereinafter, a method of forming a pattern according to embodiments will be described in more detail with reference to FIG. 1 and FIGS. 2A to 2C. FIG. 1 is a flowchart illustrating a method of forming a pattern according to embodiments, and FIGS. 2A to 2C are side cross-sectional views illustrating a method of forming a pattern according to embodiments. Hereinafter, a method of forming a pattern using a positive resist composition will be described by way of an example, but the embodiment is not limited thereto.

Referring to FIG. 1, a method of forming a pattern includes applying a resist composition to form a resist film (S101), exposing at least a portion of the resist film to high-energy rays (S102) to provide an exposed resist film, and developing the exposed resist film using a developer (S103). These operations may be omitted or may be performed in a different order, if necessary.

First, a substrate 100 is prepared. The substrate 100 may be a semiconductor substrate such as a silicon substrate and a germanium substrate, or may be formed of glass, quartz, ceramic, copper, or the like. In some embodiments, the substrate 100 may include Groups III to V compounds, such as GaP, GaAs, and GaSb.

A resist film 110 may be formed on the substrate 100 by applying the resist composition thereto to a desired thickness using a coating method. If necessary, a post application bake (PAB)) may be performed on the resist film 110 to remove the organic solvent remaining in the resist film 110. Alternatively, by heating the resist film 110, radicals may be generated, and then the radicals may be chemically bonded by exposure to form a crosslink.

As the coating method, spin coating, dipping, roller coating, or other common coating methods may be used. Among them, spin coating may be used in particular, and the resist film 110 having a desired thickness may be formed by adjusting viscosity, concentration, and/or spin speed of the resist composition. For example, the resist film 110 may have a thickness of about 10 nm to about 300 nm. For example, the resist film 110 may have a thickness of about 30 nm to about 200 nm.

A lower limit of a PAB temperature may be 60° C. or higher, or 80° C. or higher. In addition, an upper limit of the PAB temperature may be 150° C. or less, or 140° C. or lower. A lower limit of a PAB time may be 5 seconds or more, or 10 seconds or more. An upper limit of the PAB time may be 600 seconds or less, or 300 seconds or less.

Before applying the resist composition on the substrate 100, a film to be etched (not shown) may be formed on the substrate 100. The film to be etched may refer to a film onto which an image is transferred from a resist pattern to be converted into a pattern. In an embodiment, the film to be etched may be formed to include, for example, an insulating material such as a silicon oxide, a silicon nitride, and a silicon oxynitride. In some embodiments, the film to be etched may be formed to include a conductive material such as a metal, a metal nitride, a metal silicide, and a metal silicide nitride film. In some embodiments, the film to be etched may be formed to include a semiconductor material such as polysilicon.

In an embodiment, an anti-reflection film may further be formed on the substrate 100 to increase and/or maximize efficiency of the resist. The anti-reflection film may be an organic or inorganic anti-reflection film.

In an embodiment, a protective film may further be formed on the resist film 110 to reduce effects of alkaline impurities included during a process. In addition, in the case of performing immersion lithography, a protective film for immersion lithography may be formed on the resist film 110 to avoid direct contact between an immersion medium and the resist film 110.

Subsequently, at least a portion of the resist film 110 may be exposed to high-energy rays. For example, high-energy rays having passed through a mask 120 may reach at least one portion of the resist film 110. Therefore, the resist film 110 may have an exposed portion 111 and an non-exposed portion 112.

Although not limited to a specific theory, radicals are generated in the exposed portion 111 by exposure to light, and polar functional groups are generated from the radicals, which may change the properties of the resist composition.

Accordingly, the exposed portion 111 and the non-exposed portion 112 may have different water contact angles, and the difference between the water contact angle of the non-exposed portion 112 and the water contact angle of the exposed portion 111 may be 25° or more, 40° or more, 50° or more, or 60° or more.

In an embodiment, the exposure dose of the exposure may be 100 mJ/cm² or less, 80 mJ/cm² or less, 60 mJ/cm² or less, or 50 mJ/cm² or less, and the difference between the water contact angle of the non-exposed portion 112 and the water contact angle of the exposed portion 111 may be 25° or more, 40° or more, 50° or more, or 60° or more.

When the exposure dose of the exposure is 100 mJ/cm² or less, the difference between the water contact angle of the non-exposed portion 112 and the water contact angle of the exposed portion 111 may be 25° or more or 30° or more, and in particular, when the exposure dose of the above exposure is 80 mJ/cm² or less, the difference between the water contact angle of the non-exposed portion 112 and the water contact angle of the exposed portion 111 may be 25° or more 30° or more.

In some cases, the exposure may be performed by irradiating high-energy rays through a mask with a certain pattern using a liquid such as water as a medium. Examples of the high-energy rays include electromagnetic waves such as ultraviolet rays, deep ultraviolet (DUV) rays, extreme ultraviolet (EUV) rays (wavelength of 13.5 nm), X-rays, and γ-rays; and charged particle beams such as electron beams (EBs) and a particle beams. Irradiation of these high-energy rays may be collectively referred to as “exposure.”

Various light sources may be used for the exposure, for example, a light source emitting laser beams in the UV range, such as a KrF excimer laser (wavelength of 248 nm), an ArF excimer laser (wavelength of 193 nm), and an F₂ excimer laser (wavelength of 157 nm), a light source emitting harmonic laser beams in the far ultraviolet or vacuum ultraviolet range by converting wavelengths of laser beams received from a solid laser light source (YAG or semiconductor laser), and a light source emitting EBs or EUVs may be used. During exposure, the exposure may be usually performed through a mask corresponding to a desired pattern, but when exposure light is an EB, the exposure may be performed through direct writing without using a mask.

The integrated dose of high-energy rays, for example, when using extreme ultraviolet rays as high-energy rays, may be 2000 mJ/cm² or less, 500 mJ/cm² or less, or 100 mJ/cm² or less. In addition, when EBs are used as the high-energy rays, the integral dose may be 5,000 μC/cm² or less, or 1,000 μC/cm² or less.

In addition, a post-exposure bake (PEB) may be performed after exposure. The lower limit of the temperature of PEB may be 50° C. or more, or 80° C. or more. The upper limit of the PEB temperature may be 250° C. or lower, or 200° C. or lower. The lower limit of the time of the PEB time may be 5 seconds or more, or 10 seconds or more. The upper limit of the time of the PEB may be 600 seconds or less, or 300 seconds or less.

Next, the exposed resist film 110 may be developed using a developer. The exposed portion 111 may be removed by being washed away by the developer, and the non-exposed portion 112 remains without being washed away by the developer.

Examples of the developer include a distilled water, an alkaline developer, and a developer including an organic solvent (hereinafter also referred to as “organic developer”). Examples of a developing method are a dipping method, a puddle method, a spray method, a dynamic injection method, and the like. A developing temperature may be, for example, about 5° C. or more and about 60° C. or less, and a developing time may be, for example, about 5 seconds or more and about 300 seconds or less.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of an amount of the alkaline compound included in the alkaline developer may be 0.1 wt % or more, 0.5 wt % or more, or 1 wt % or more. Additionally, an upper limit of the amount of the alkaline compound included in the alkaline developer may be 20 wt % or less, 10 wt % or less, or 5 wt % or less.

Examples of the organic solvent included in the organic developer may include the same organic solvents as those examples in the part of <Solvent> of [Resist composition]. For example, n-butyl acetate (nBA), propylene glycol methyl ether (PGME), propylene glycol methyl ether acetate (PGMEA), γ-butyrolactone (GBL), isopropanol (IPA), and the like may be used as the organic developer. The organic developer may further include organic acids such as acetic acid, formic acid, and citric acid.

The lower limit of the organic solvent content in the organic developer may be 80 wt % or more, 90 wt % or more, 95 wt % or more, or 99 wt % or more.

Organic developer may also include surfactants. Additionally, organic developer may include trace amounts of moisture. Additionally, during development, it is possible to stop the development process by replacing the organic developer with a different type of solvent.

Additionally, the developer may be used alone or in combination of two or more types.

The resist pattern after development may be further cleaned. Pure water, ultrapure water and rinse solution may be used as cleaning solution. There are no particular restrictions on the rinse solution as long as it does not dissolve the resist pattern, and common solutions containing organic solvents may be used. For example, the rinse liquid may be alcohol-based solvents or ester-based solvents. After cleaning, any remaining rinse solution on the substrate and pattern may be removed. Additionally, when ultrapure water is used, any remaining water on the substrate and pattern may be removed.

As described above, after forming the resist pattern, a patterned wiring substrate may be obtained by etching. The etching method may be carried out using well-known methods such as dry etching with plasma gas, and wet etching with alkaline solutions, copper (II) chloride solutions, or iron (III) chloride solutions.

After forming the resist pattern, plating may also be performed. The plating method is not particularly limited, but examples include copper plating, solder plating, nickel plating, and gold plating.

The remaining resist pattern after etching may be stripped using an organic solvent. Examples of such organic solvents include, but are not limited to, propylene glycol monomethyl ether acetate (PGMEA), propylene glycol monomethyl ether (PGME), and ethyl lactate (EL). The stripping method is not particularly limited and may include, for example, immersion methods and spray methods. Additionally, the wiring substrate with the resist pattern formed may be a multilayer wiring substrate and may have small-diameter through holes.

In an embodiment, the wiring substrate is formed by depositing metal in a vacuum after forming the resist pattern, and then dissolving the resist pattern in a solution, a method known as the lift-off method.

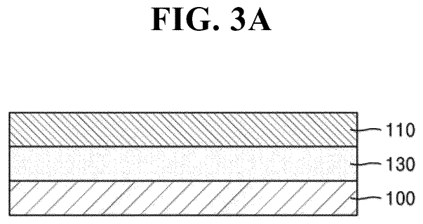

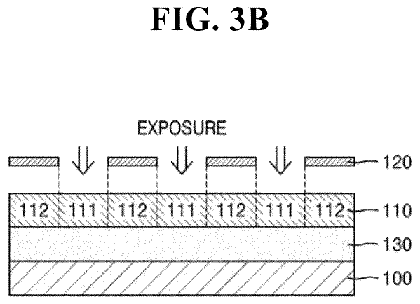

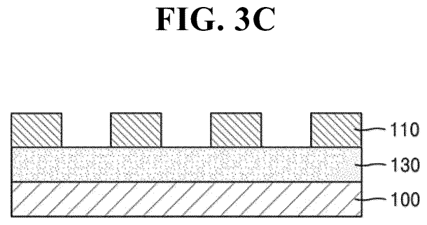

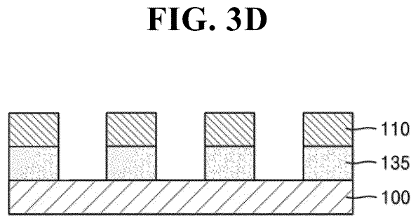

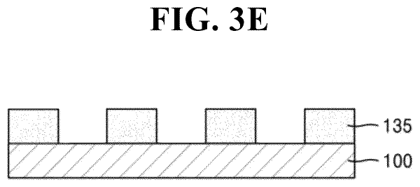

FIGS. 3A to 3E are side cross-sectional views showing a method of forming a patterned structure according to an embodiment.

As shown in FIG. 3A, a material layer 130 may be formed on the substrate 100 before forming the resist film 110 on the substrate 100. The resist film 110 may be formed on top of the material layer 130. The material layer 130 may include an insulating material (e.g., silicon oxide, silicon nitride), a semiconductor material (e.g., silicon), or a metal (e.g., copper). In some embodiments, the material layer 130 may have a multi-layer structure. The material of the material layer 130 may be different from the material of the substrate 100.

As shown in FIG. 3B, the resist film 110 may undergo a prebake process before exposure and then be exposed to high-energy rays through the mask 120, and subsequently the resist film 110 may include exposed portion 111 and non-exposed portion 112.

As shown in FIG. 3C, the exposed resist film 110 may be developed using a developer. The exposed portion 111 may be washed away by the developer, while the non-exposed portion 112 remains intact.

As shown in FIG. 3D, the resist pattern 110 may serve as a mask for etching the exposed portions of the material layer 130 to form the material pattern 135 on the substrate 100.

As shown in FIG. 3E, the resist pattern 110 may be removed.

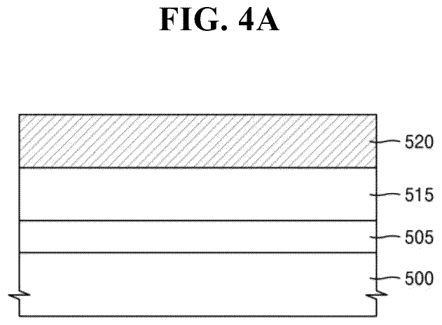

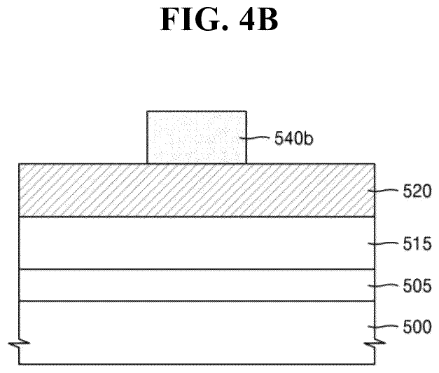

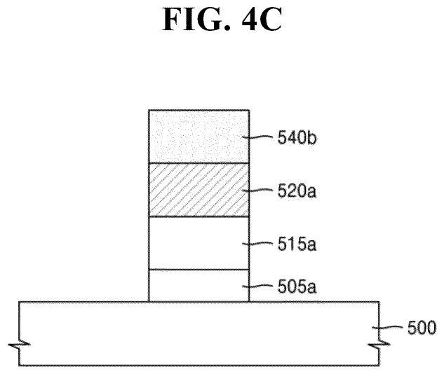

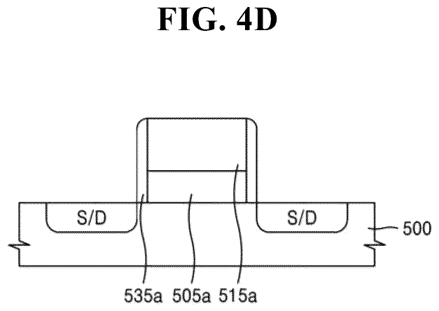

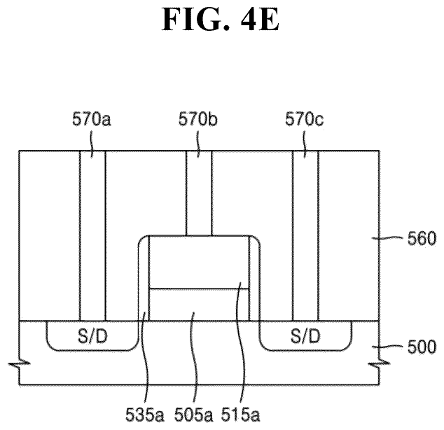

FIGS. 4A to 4E are side cross-sectional views showing a method of forming a semiconductor device according to an embodiment.

As shown in FIG. 4A, a gate dielectric 505 (e. g., silicon oxide) may be formed on the substrate 500. The substrate 500 may be a semiconductor substrate such as a silicon substrate. A gate layer 515 (e.g., doped polysilicon) may be formed on gate dielectric 505. A hardmask layer 520 may be formed on the gate layer 515.

As shown in FIG. 4B, a resist pattern 540b may be formed on the hardmask layer 520. The resist pattern 540b may be formed using a resist composition according to an embodiment. The resist composition may include an organic solvent.

As shown in FIG. 4C, the gate layer 515 and the gate dielectric 505 may be etched to form a hardmask pattern 520a, a gate electrode pattern 515a, and a gate dielectric pattern 505a.

As shown in FIG. 4D, the hard mask pattern 520a optionally may be removed and a spacer layer may be formed on the gate electrode pattern 515a and the gate dielectric pattern 505a. The spacer layer may be formed using a deposition process (e.g., CVD). The spacer layer may be etched to form spacers 535a (e.g., silicon nitride) on the sidewalls of the gate electrode pattern 515a and the gate dielectric pattern 505a. After forming the spacers 535a, ions may be implanted into the substrate 500 to form source/drain impurity regions (S/D).

As shown in FIG. 4E, an interlayer insulating film 560 (e.g., an oxide) may be formed on the substrate 500, covering the gate electrode pattern 515a, gate dielectric pattern 505a, and spacers 535a. Subsequently, the interlayer insulating film 560 may have electrical contacts 570a, 570b, and 570c formed to connect with the gate electrode 515a and the S/D regions. The electrical contacts (570a, 570b, 570c) may be formed of a conductive material (e.g., metal). Although not shown, a barrier layer may be formed between the sidewalls of the interlayer insulating film 560 and the electrical contact portions 570a, 570b, 570c.

FIGS. 4A to 4E show examples of forming transistors, but the disclosure is not limited thereto.

For example, although not illustrated in FIGS. 4D and 4E, in some embodiments, the hard mask pattern 520a may not be removed before the spacer 535a is formed. For example, if the hard mask pattern 520a is not removed, then the hard mask pattern 520a may remain on top of the gate electrode 515a in FIGS. 4D and 4E, the spacer 535a may cover a sidewall of the hard mask pattern 520a in FIGS. 4D and 4E, and the electrical contact 570b may extend through an opening in the hard mask pattern 520a to directly contact an upper surface of the gate electrode 515a.

The resist composition according to an embodiment may be used in the patterning process to form other types of semiconductor devices.

While the disclosure will be described in more detail using the following examples and comparative examples, the technical scope of the disclosure is not limited to these examples.

### EXAMPLES

### Synthesis Example 1: Synthesis of OM-A

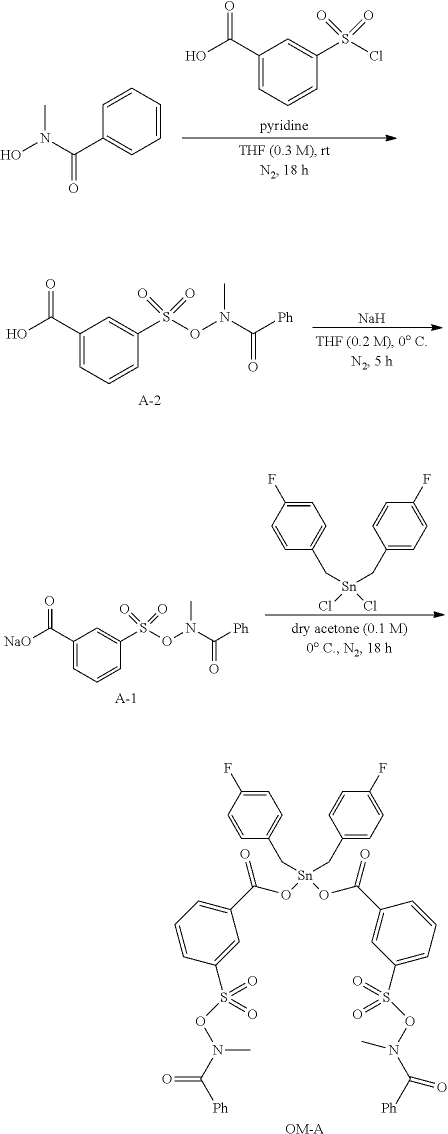

### (1) Synthesis of Compound A-2

N-hydroxy-N-methylbenzamide (0.5 g, 3.31 mmol) was placed in a nitrogen (N₂)-purged 2-necked round bottom flask (RBF), and diluted with THF (5 ml). To this, pyridine (0.54 ml, 6.62 mmol) was added at 0° C., followed by the dropwise addition of a THF solution of 3-(chlorosulfonyl)benzoic acid (0.73 g, 3.31 mmol) (6 ml of THF, total volume 11 ml, 0.3 M). The reaction mixture was then allowed to warm to room temperature and stirred for 18 hours. After confirming the reaction completion, the mixture was diluted with ethyl acetate (EA), 1N HCl (3 ml) was added, and the organic layer was washed three times with distilled water. The collected organic layer was dried with Na₂SO₄, and the solvent was removed. After purification using short column chromatography (eluent: MC:MeOH (MeOH 5 v %)), the residue was recrystallized using EA/n-hexane to obtain Compound A-2 (0.24 g, yield:21%).

¹H NMR (500 MHz, DMSO) δ 13.49 (s, ¹H), 8.30-8.22 (m, 2H), 8.17 (dt, J=7.9, 1.4 Hz, ¹H), 7.75 (t, J=7.8 Hz, ¹H), 7.53-7.45 (m, ¹H), 7.41-7.29 (m, 4H), 3.34 (s, 3H).

¹³C NMR (126 MHz, DMSO) δ 170.95, 165.33, 135.77, 133.13, 132.91, 132.19, 131.81, 131.75, 130.40, 129.26, 128.44, 128.02, 41.32

### (2) Synthesis of Compound A-1

Sodium hydride (0.18 g, 4.5 mmol) was placed in an RBF, and diluted with THF (22 ml, 0.2 M) following N₂ purging. To this, Compound A-2 (1.5 g, 4.5 mmol) was added at 0° C. The reaction mixture was then stirred at 0° C. for 5 hours. After removing the solvent, the residue was recrystallized with a mixture of THF:Et₂O=1:5 (10 ml:50 ml), then filtered to obtain Compound A-1 (1.4 g, yield:89%).

¹H NMR (500 MHz, DMSO) δ 8.39 (t, J=1.8 Hz, ¹H), 8.20 (dt, J=7.6, 1.4 Hz, ¹H), 7.79 (ddd, J=7.8, 2.1, 1.2 Hz, ¹H), 7.55-7.47 (m, 2H), 7.43-7.35 (m, 4H), 3.21 (s, 3H).

¹³C NMR (126 MHz, DMSO) δ 171.16, 166.54, 142.19, 135.51, 132.13, 131.91, 131.69, 129.38, 128.69, 128.61, 128.46, 128.02, 41.05

### (3) Synthesis of Compound OM-A

Dichlorobis(4-fluorobenzyl)stannane (0.5 g, 1.23 mmol) was placed in a RBF followed by N₂ purging. To this, acetone (12.3 ml, 0.1 M) was added for dilution, followed by addition of Compound A-1 (0.88 g, 2.45 mmol) at 0° C. The reaction mixture was stirred at 0° C. for 18 hours, then filtered through celite. The solvent was removed from the filtrate, and the residue was recrystallized from a mixture of dichloromethane: n-hexane (1:10, 5 ml:50 ml). After filtration, the filtrate was dried under vacuum to obtain Compound OM-A (0.85 g, yield:69%).

¹H NMR (500 MHz, CD2Cl2) δ 8.47 (t, J=1.9 Hz, 2H), 8.15 (d, J=7.8 Hz, 2H), 8.03 (dt, J=7.9, 1.5 Hz, 2H), 7.56 (t), J=7.9 Hz, 2H), 7.47-7.30 (m, 10H), 7.05-6.94 (m, 4H), 6.79-6.70 (m, 4H), 3.48 (s, 6H), 3.14 (s, 4H).

¹³C NMR (126 MHz, CD2Cl2) δ 173.84, 171.75, 161.42 (d, J=243.9 Hz), 136.50, 134.66, 133.71, 132.64, 132.18, 131.60, 131.27, 130.45 (d, J=8.2 Hz), 129.88, 128.84, 128.74, 115.65 (d, J=21.8 Hz), 41.81, 32.38.

¹¹⁹Sn NMR (186 MHz, CD2Cl2) δ −246.47.

¹⁹F NMR (471 MHz, CD2Cl2) δ −118.70.

### Evaluation Example 1: Thin Film Phenomenon Evaluation

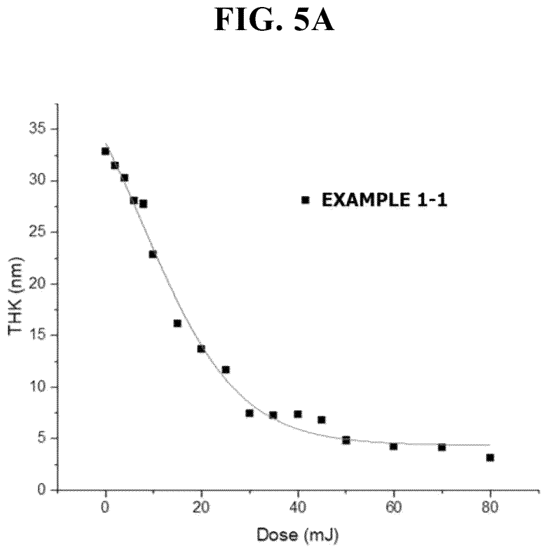

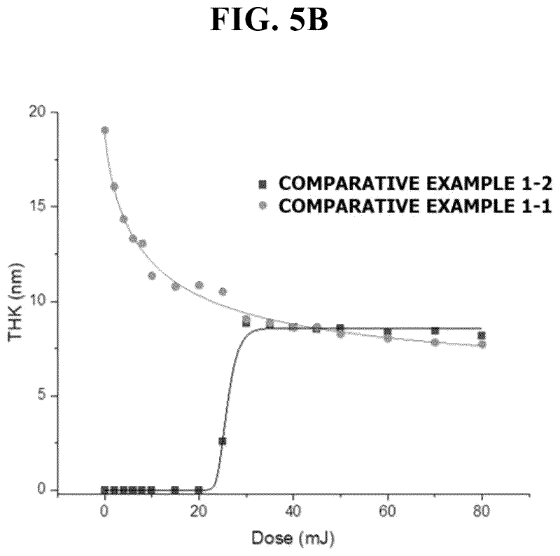

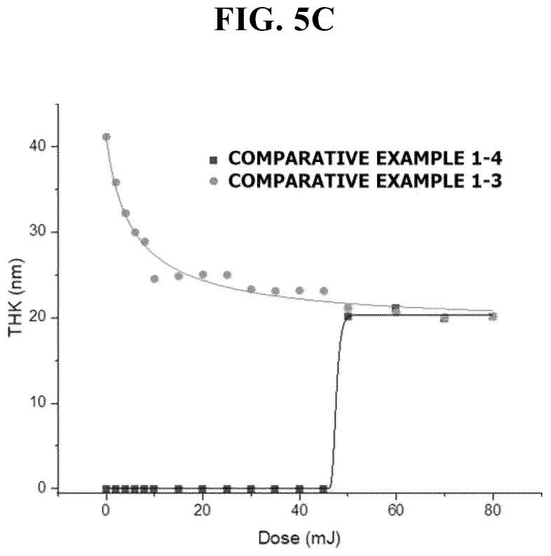

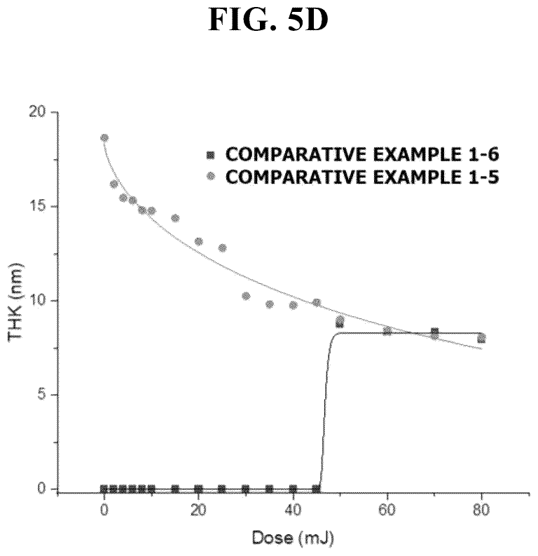

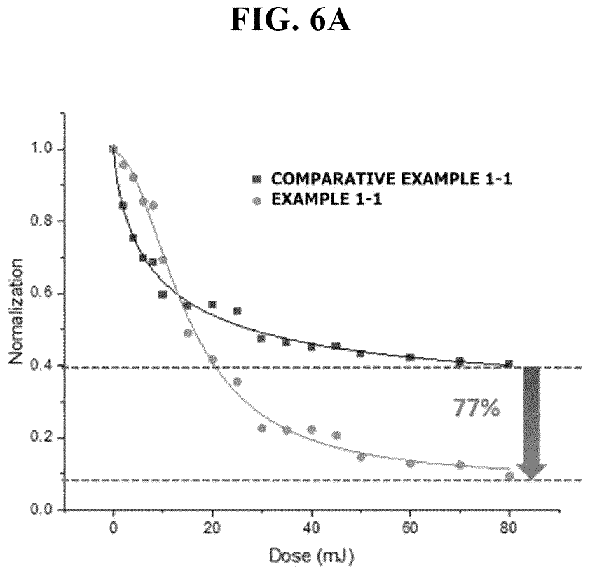

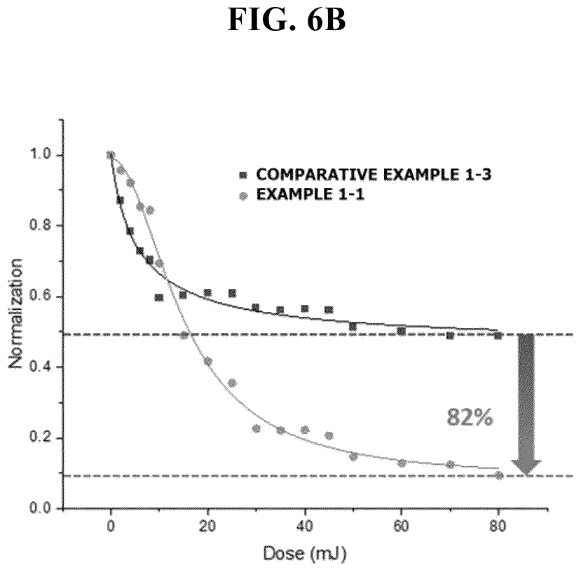

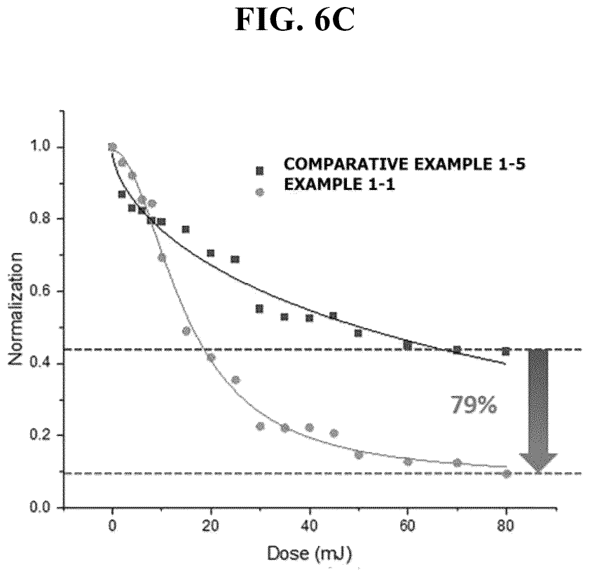

The organometallic compound synthesized in Synthesis Example 1 was dissolved in the casting solvent described in Table 1 at the concentration described in Table 1 to prepare a casting solution. After treating a 4-inch diameter silicon wafer with O₂ plasma for 30 minutes, the wafer was spin-coated with the casting solution at the coating speed specified in Table 1 for 1 minute, followed by performing PAB at 110° C. for 1 minute to form a film with the initial thickness shown in Table 1. Next, a mask (4 cm×4 cm) with a thickness of 1 cm and rectangular holes (1 cm×1 cm) was placed on top of the film, and each hole was exposed to deep ultraviolet (DUV) radiation at a wavelength of 254 nm with doses of 0 mJ/cm² to 80 mJ/cm², and performed PEB at 170° C. for 90 seconds. The dried film was immersed in either distilled water (DI) or a PGMEA solution with 2 wt % acetic acid (PGMEA (2 wt % A.A.)) as the developer for 60 seconds at 25° C., after which the remaining film thickness was measured and recorded in Table 1 and FIGS. 5A to 5D. Additionally, the relative values of the film thickness for Example 1-1 and Comparative Examples 1-1, 1-3, and 1-5 were compared, as shown in FIGS. 6A to 6C. Here, the residual film ratio refers to the ratio of the film thickness at 0 mJ/cm² to the film thickness at 80 mJ/cm² after development.

TABLE 1

| | | | | | | | | | Residual | |
|---|---|---|---|---|---|---|---|---|---|---|
| | | Casting Solution | | | Coating | Initial | | | Film | |
| | Organometallic | Casting | Concentration | PAB | Speed | Thickness | | PEB | Ratio | |
| | Compound | Solvent | (wt %) | (° C) | (rpm) | (nm) | Developer | (C) | (%) | Graph |
| Example | OM- | Cyclohexanone | 2 | 110 | 2000 | 40 | DI | 170 | 9 | FIG. 5A |
| 1-1 | A | | | | | | | | | |
| Comparative | C-1 | Cyclohexanone | 2 | 110 | 2000 | 20 | DI | 170 | 40 | FIG. 5B |
| Example | | | | | | | | | | |
| 1-1 | | | | | | | | | | |
| Comparative | C-1 | Cyclohexanone | 2 | 110 | 2000 | 20 | PGM | 170 | — | FIG. 5B |
| Example | | | | | | | EA | | | |
| 1-2 | | | | | | | (2 | | | |
| | | | | | | | wt % | | | |
| | | | | | | | A.A.) | | | |
| Comparative | C-1 | Cyclohexanone | 3 | 110 | 1200 | 45 | DI | 170 | 49 | FIG. 5C |
| Example | | | | | | | | | | |
| 1-3 | | | | | | | | | | |
| Comparative | C-1 | Cyclohexanone | 3 | 110 | 1200 | 45 | PGM | 170 | — | FIG. 5C |
| Example | | | | | | | EA | | | |
| 1-4 | | | | | | | (2 | | | |
| | | | | | | | wt % | | | |
| | | | | | | | A.A.) | | | |
| Comparative | C-2 | Cyclohexanone | 2 | 110 | 2000 | 30 | DI | 170 | 43 | FIG. 5D |
| Example | | | | | | | | | | |
| 1-5 | | | | | | | | | | |
| Comparative | C-2 | Cyclohexanone | 2 | 110 | 2000 | 29 | PGM | 170 | — | FIG. 5D |
| Example | | | | | | | EA | | | |
| 1-6 | | | | | | | (2 wt % | | | |
| | | | | | | | A.A.) | | | |

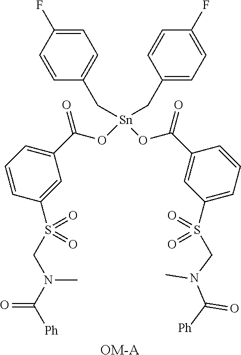

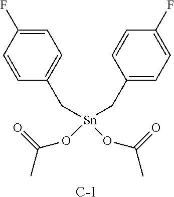

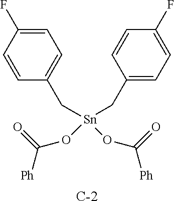

Referring to Table 1, FIGS. 5A to 5D, and FIGS. 6A to 6C, when comparing the residual film ratios of Example 1-1 with Comparative Examples 1-1, 1-3, and 1-5, it was confirmed that the residual film ratio of Example 1-1 improved by 77%, 82%, and 79%, respectively, compared to Comparative Examples 1-1, 1-3, and 1-5. This confirmed that the resist composition of Example 1-1 has significantly improved solubility in DI water compared to the resist compositions of Comparative Examples 1-1, 1-3, and 1-5.

### Evaluation Example 2: Water Contact Angle (WCA) Evaluation

The organometallic compound synthesized in Synthesis Example 1 was dissolved in cyclohexanone casting solvent at a concentration of 2 wt % to prepare a casting solution. After treating a 4-inch diameter silicon wafer with O₂ plasma for 30 minutes, the wafer was spin-coated with the casting solution at 2000 rpm for 1 minute, followed by performing PAB at 110° C. for 1 minute to form a film with an initial thickness of 40 nm. Next, a mask (4 cm×4 cm) with a thickness of 1 cm and rectangular holes (1 cm×1 cm) was placed on top of the film, and each hole was exposed to deep ultraviolet (DUV) radiation at a wavelength of 254 nm with doses ranging from 0 mJ/cm² to 100 mJ/cm², then PEB was performed at 170° C. for 90 seconds. Afterward, 3 μL of water was dropped on each hole, and the water contact angle (unit: °) was measured, and the results are shown in Table 2.

TABLE 2

| | | Dose (mJ/cm²) | | | | | | | | | | |
|---|---|---|---|---|---|---|---|---|---|---|---|---|
| | Organometallic Compound | 0 | 10 | 20 | 30 | 40 | 50 | 60 | 70 | 80 | 90 | 100 |
| Example 2-1 | OM-A | 73.5 | 63.9 | 65.1 | 67.8 | 70.2 | 37.7 | 40.3 | ~10 | 0 | 0 | 0 |

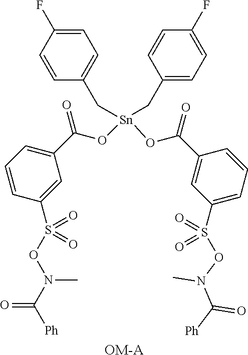

Referring to Table 2, it was found that the water contact angle of the resist composition in Example 2-1 significantly changed before and after DUV irradiation, confirming that a polarity change occurred in the organometallic compound.

Embodiments of the disclosure may provide a resist composition having improved sensitivity and providing a pattern with improved resolution.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An organometallic compound represented by the following Formula 1: 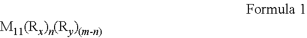
wherein, in Formula 1,
M₁₁ is indium (In), tin (Sn), antimony (Sb), tellurium (Te), thallium (Tl), lead (Pb), bismuth (Bi), or polonium (Po),
Rₓ is *—X₁-(L₁)ₐ₁-[Y₁—Z₁]_{c1},
R_{y} is *-(L₂)ₐ₂-(R₁)_{b1},
n is an integer from 1 to 6,
m is an integer from 1 to 6,
m-n is 0 or more,
a plurality of Rₓ are identical to or different from each other,
a plurality of R_{y} are identical to or different from each other,
X₁ is O, OC(═O), C(═O)O, OS(═O), S(═O)O, OS(═O)₂, S(═O)₂O, S, SC(═O) or C(═O)S,
Y₁ is OC(═O), C(═O)O, OS(═O)₂ or S(═O)₂O,
Z₁ is *—C(R₂)(R₃)(R₄), *—C(R₂)═N(R₃), C(R₂)(R₃)═N—* or *—N(R₂)(R₃),
L₁ and L₂ are each independently a linear, branched or cyclic C₁-C₃₀ divalent hydrocarbon group optionally including a heteroatom,
a1 and a2 are each independently an integer from 0 to 4,
R₁ is a linear, branched or cyclic C₁-C₃₀ monovalent hydrocarbon group optionally including a heteroatom, and an adjacent two of the plurality of R₁ are optionally bound to each other to form a ring,
R₂ to R₄ are each independently hydrogen, deuterium, a halogen atom, a cyano group, a hydroxyl group, or a linear, branched or cyclic C₁-C₃₀ monovalent hydrocarbon group optionally including a heteroatom, and an adjacent two of the plurality of R₂ to R₄ are optionally bound to each other to form a ring,
b1 and c1 are each independently an integer from 1 to 4, and
* is a bonding site with a neighboring atom.

2. The organometallic compound of claim 1,
wherein M₁₁ is Sn, Sb, Te or Bi.

3. The organometallic compound of claim 1,
wherein n is an integer from 1 to 4,
m is an integer from 1 to 3, and
M₁₁ is Sn.

4. The organometallic compound of claim 1,
wherein a bond between M₁₁ and Rₓ is an M₁₁-oxygen single bond or an M₁₁-sulfur single bond, and
a bond between M₁₁ and R_{y} is an M₁₁-carbon single bond.

5. The organometallic compound of claim 1,
wherein R₁ is a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ an aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group,
R₂ to R₄ are each independently hydrogen, deuterium, a halogen atom, a cyano group, a nitro group, a hydroxyl group, —C(═O)R₅, —C(R₅)═NR₆, —OR₅, —S(═O)R₅, —S(═O)₂R₅, —S(═O)₂OR₅, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group, and
R₅ and R₆ are each independently hydrogen, deuterium, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₅-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group.

6. The organometallic compound of claim 1,
wherein R₁ is selected from a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₅-C₂₀ cycloalkyl group, a C₆-C₂₀ aryl group, a C₁-C₂₀ heteroaryl group, or a combination thereof,
R₂ to R₄ are each independently selected from: hydrogen; deuterium; a halogen atom; a cyano group; a nitro group; a hydroxyl group; —C(═O)R₅; —C(R₅)═NR₆; —S(═O)₂R₅; and a C₁-C₃₀ alkyl group, a C₃-C₃₀ cycloalkyl group, a C₂-C₃₀ alkenyl group, a C₅-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or a combination thereof, and
R₅ and R₆ are each independently selected from: hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or a combination thereof.

7. The organometallic compound of claim 1,
wherein Z₁ is represented by any one of Formulae 4-1 to 4-9: 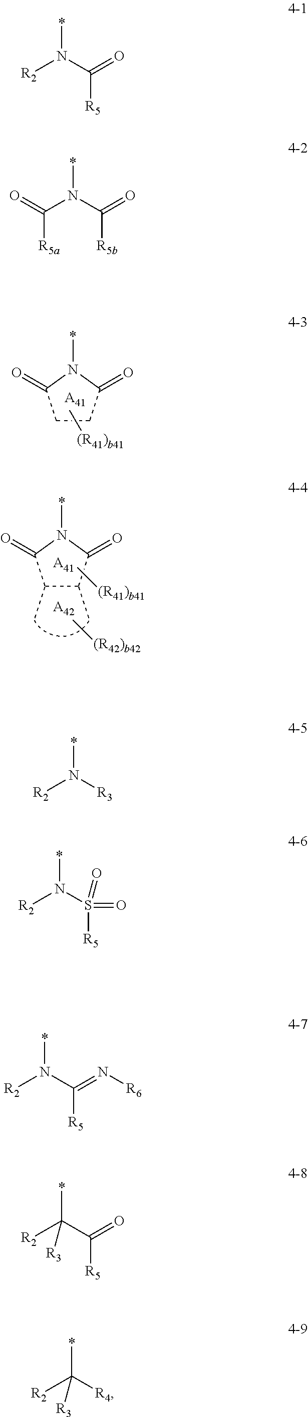
wherein, in Formulae 4-1 to 4-9,
R₂ to R₄ are each independently selected from: hydrogen; deuterium; a halogen atom; a cyano group; a nitro group; a hydroxyl group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or a combination thereof,
R₅, R₅ₐ and R_{5b} are each independently selected from: hydrogen; deuterium; and a C₁-C₃₀ alkyl group, a C₅-C₃₀ cycloalkyl group, a C₂-C₃₀ alkenyl group, a C₅-C₃₀ cycloalkenyl group, a C₂-C₃₀ alkynyl group, a C₆-C₃₀ aryl group and a C₇-C₃₀ arylalkyl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₅-C₂₀ cycloalkyl group, a C₆-C₂₀ aryl group, a C₁-C₂₀ heteroaryl group, or a combination thereof,
an adjacent two selected from: R₂ to R₅; R₅ₐ; and R_{5b} are optionally bound to each other to form a ring,
A₄₁ and A₄₂ are each independently a cyclic C₁-C₃₀ alkyl group optionally including a heteroatom or a C₁-C₃₀ aryl group optionally including a heteroatom,
R₄₁ and R₄₂ are each independently hydrogen, deuterium, a halogen atom, a hydroxyl group, a cyano group, a nitro group, a C₁-C₂₀ alkyl group, a C₁-C₂₀ halogenated alkyl group, a C₃-C₂₀ cycloalkyl group, a C₆-C₂₀ aryl group, or a C₁-C₂₀ heteroaryl group,
b41 and b42 are each independently an integer from 1 to 10, and
* is a bonding site with a neighboring atom.

8. The organometallic compound of claim 1,
wherein b1 is 2, 3, or 4, and
R₁ is selected from a C₂-C₃₀ alkenyl group, a C₃-C₃₀ cycloalkenyl group, a C₂-C₃₀ alkynyl group and a C₆-C₃₀ aryl group, each unsubstituted or substituted with deuterium, a halogen atom, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

9. The organometallic compound of claim 1,
wherein at least one of R₂ to R₄ is an electron-withdrawing group.

10. The organometallic compound of claim 1,
wherein the organometallic compound represented by Formula 1 is represented by any one of Formulae 1-1 to 1-4: 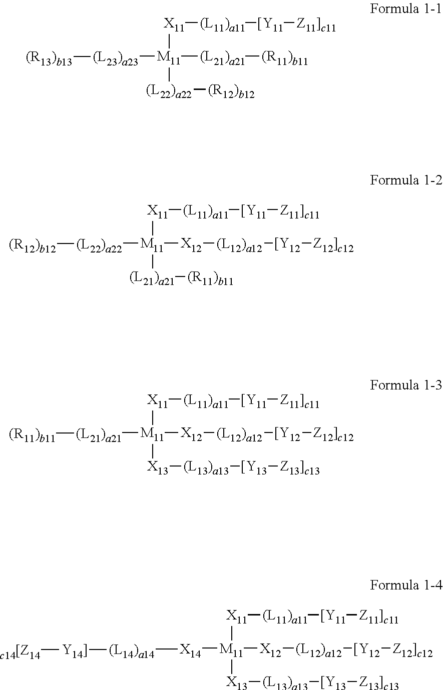
wherein, in Formulae 1-1 to 1-4,
M₁₁ is the same as the definition of M₁₁ in Formula 1,
L₁₁ to L₁₄ are each independently the same as the definition of L₁ in Formula 1,
L₂₁ to L₂₃ are each independently the same as the definition of L₂ in Formula 1,
a11 to a14 are each independently the same as the definition of a1 in Formula 1,
a21 to a23 are each independently the same as the definition of a2 in Formula 1,
R₁₁ to R₁₃ are each independently the same as the definition of R₁ in Formula 1,
b11 to b13 are each independently the same as the definition of b1 in Formula 1,
Y₁₁ to Y₁₄ are each independently the same as the definition of Y₁ in Formula 1,
X₁₁ to X₁₄ are each independently the same as the definition of X₁ in Formula 1,
Z₁₁ to Z₁₄ are each independently the same as the definition of Z₁ in Formula 1, and
c11 to c14 are each independently the same as the definition of c1 in Formula 1.

11. The organometallic compound of claim 1,
wherein the organometallic compound represented by Formula 1 is selected from compounds in Group I:

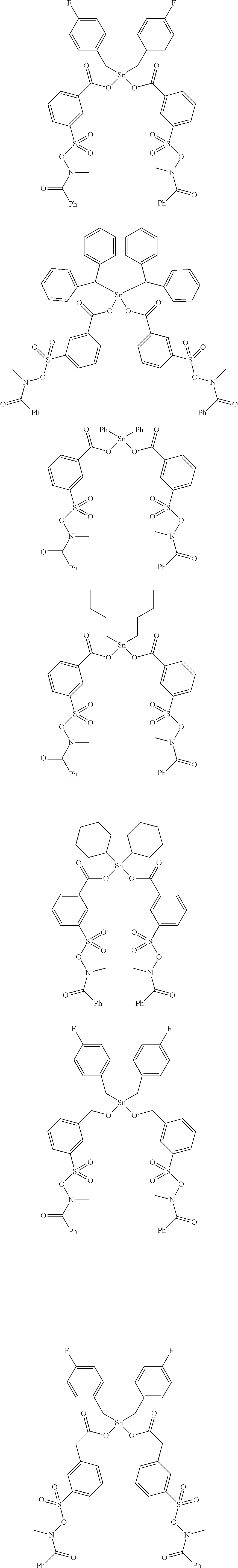

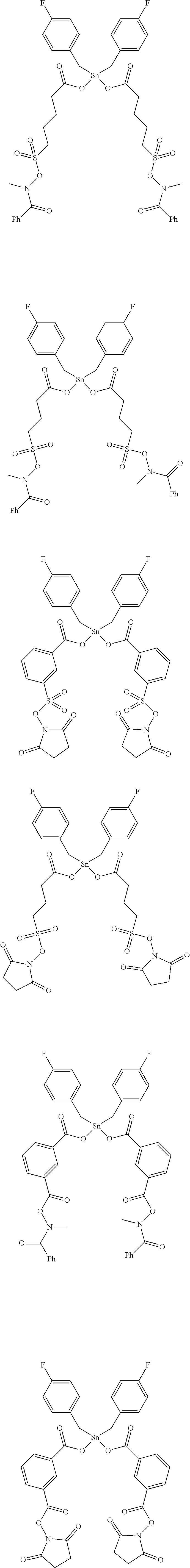

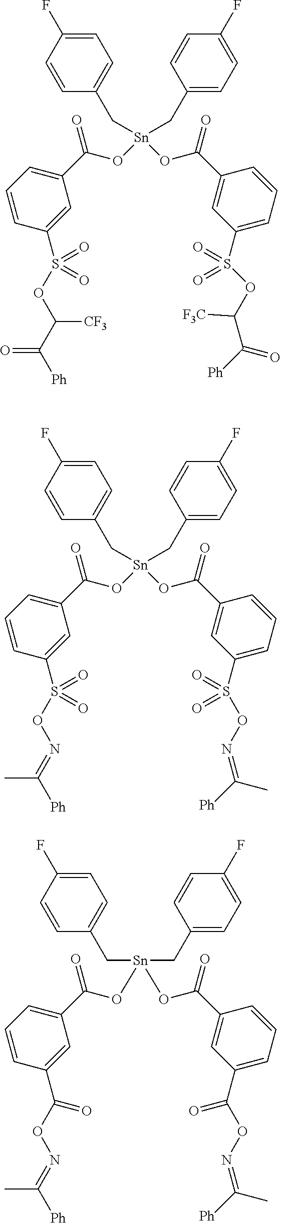

12. A resist composition comprising:
the organometallic compound of claim 1.

13. The resist composition of claim 12, wherein
the resist composition is substantially free of a photoacid generator.

14. The resist composition of claim 12, wherein the
the resist composition is substantially free of a compound having a molecular weight of 1,000 or more.

15. The resist composition of claim 12, further comprising:
an organic solvent.

16. The resist composition of claim 15,
wherein the organic solvent is a polar aprotic solvent.

17. A method of forming a pattern, the method comprising:
forming a resist film by applying the resist composition of claim 12 on a substrate;
exposing at least a portion of the resist film to high-energy rays to provide an exposed resist film; and
developing the exposed resist film using a developer.

18. The method of claim 17,
wherein the exposing is performed by irradiating the resist film using at least one of ultraviolet rays, deep ultraviolet (DUV) rays, extreme ultraviolet (EUV) rays, X-rays, Y-rays, electron beams (EBs), and a particle beams.

19. The method of claim 17,
wherein the exposed resist film includes an exposed portion and a non-exposed portion, and
the exposed portion is removed in the developing the exposed resist film.

20. The method of claim 17,
wherein the exposed resist film includes an exposed portion and a non-exposed portion, and
a difference between a water contact angle of the non-exposed portion and a water contact angle of the exposed portion is 25° or more.
